(19) United States
(12) Patent Application Publication
(10) Pub. No.: US 2014/0137938 A1
(43) Pub. Date: May 22, 2014

(54) PROTECTIVE SHEET FOR SOLAR CELLS, METHOD FOR PRODUCING SAME, BACK SHEET FOR SOLAR CELLS, AND SOLAR CELL MODULE

(71) Applicant: FUJIFILM CORPORATION, Tokyo (JP)

(72) Inventor: Ryuta TAKEGAMI, Kanagawa (JP)

(73) Assignee: FUJIFILM CORPORATION, Tokyo (JP)

(21) Appl. No.: 14/152,206

(22) Filed: Jan. 10, 2014

Related U.S. Application Data
(63) Continuation of application No. PCT/JP2012/067946, filed on Jul. 13, 2012.

(30) Foreign Application Priority Data
Jul. 14, 2011 (JP) 2011-155558

(51) Int. Cl. H01L 31/048; H01L 31/18

(52) U.S. Cl. CPC H01L 31/0487; H01L 31/18
USPC 136/256; 427/74

(57) ABSTRACT

A solar cell protective sheet comprising a polyester support having a thickness of from 145 μm to 300 μm, a thermal shrinkage in an in-plane first direction after aged at 150° C. for 30 minutes of from 0.2 to 1.0% and a thermal shrinkage in a second direction perpendicular to the first direction of from −0.3 to 0.5%, and a polymer layer arranged on the polyester support and having a residual solvent amount of at most 0.1% by mass, is excellent in adhesiveness between the polyester support and the functional layer formed thereon by water-based coating and can maintain a good shape when kept in a high-temperature high-humidity environment.

### CROSS-REFERENCE TO RELATED APPLICATIONS

This application is a continuation application of International Application No. PCT/JP2012/067946, filed Jul. 13, 2012, which in turn claims the benefit of priority from Japanese Application No. 2011-155558, filed Jul. 14, 2011, the disclosures of which applications are incorporated by reference herein in their entirety.

### BACKGROUND OF THE INVENTION

1. Technical Field

The present invention relates to a solar cell protective sheet and its production method, and to a back sheet for solar cells as well as to a solar cell module. In particular, the invention relates to a solar cell protective sheet excellent in adhesiveness between the support and the coating layer thereof, and to a method for producing the protective sheet.

2. Background Art

A solar cell module is an environmental load-reducing power generation system that releases no carbon dioxide in power generation and has become greatly popularized recently. A solar cell module is generally so designed that a solar cell element is sandwiched and sealed up with a sealant between the front substrate arranged on the front side on which sunlight falls, and the sheet, so-called back sheet arranged on the side (back side) opposite to the sunlight incident front side, in which the space between the front substrate and the solar cell element and the space between the solar cell element and the back sheet each are sealed up with an EVA (ethylene-vinyl acetate) resin or the like.

The back sheet that constitutes the solar cell module acts to protect the solar cell module from penetration of water through the back thereof, for which heretofore used is glass, fluororesin, etc. Recently, however, a polymer sheet has become used from the viewpoint of the cost thereof, etc. As the front substrate, a glass substrate is generally used from the viewpoint that its light transmittance is high it can maintain a relatively high strength. However, the recent approach in the art is to use a polymer sheet in place of the glass substrate.

The polymer sheet for use for such a solar cell protective sheet may comprise a polyester support and a functional layer as provided thereon in accordance with the desired characteristics. For example, a solar cell back side-protective sheet (back sheet) is used on the back side of a solar cell and is desired to have weather resistance, electric insulation, mechanical protection, adhesiveness to Si cell sealant, etc. As the back sheet provided with such a functional layer, PATENT DOCUMENT 1 proposes a coating layer-type back sheet, and PATENT DOCUMENT 2 proposes a laminate-type back sheet.

The coating layer-type back sheet is produced by applying a solution or a dispersion prepared by dissolving or dispersing a functional material in an organic solvent or in water, onto a support sheet of a polyester or the like at room temperature or at a suitable high temperature. The advantage of the coating layer-type back sheet is that the production cost could be reduced as compared with the laminate-type back sheet described in PATENT DOCUMENT 2. On the other hand, as the disadvantage of the coating layer-type back sheet, it is known that the adhesiveness between the support sheet and the functional layer is poor since the functional layer is provided on the sheet not using an adhesive.

On the other hand, with the requirement for applicability to thin-film solar cells that have been developed recently and for weight reduction of glass substrates, the back sheet has become desired not to give any unnecessary stress to the other members constituting a solar cell. In particular, it has now become investigated to install solar cell modules in high-temperature high-humidity environments in which the back sheet itself would be deformed, and especially it is desired to maintain the shape of the back sheet in high-temperature high-humidity environments.

### CITATION LIST

### Patent Documents

PATENT DOCUMENT 1: JP-T 2010-519742
PATENT DOCUMENT 2: JP-A 2007-150084

### SUMMARY OF THE INVENTION

### Problems that the Invention is to Solve

In fact, the present inventors investigated the solar cell protective sheet described in PATENT DOCUMENT 1, and have known that the adhesiveness between the polyester support and the functional layer formed thereon by water-based coating is still unsatisfactory. Here, the polyester support of a polymer support has a problem in that, irrespective of whether the polyester is a crystalline polyester or an amorphous polyester, the interlayer adhesiveness between the polyester support and the polymer layer formed and laminated thereon by water-based coating generally tends to be poor since the polyester has a large contact angle to water and therefore the coating liquid could not well wet the support to spread thereon (reference literature, Polymer Latex, p. 191, by Shin Koubunshi Bunko (1988)).

Further, the inventors have known that, when the back sheet described in PATENT DOCUMENT 1 is kept in a high-humidity high-temperature environment at 120° C. and at a relative humidity of 100%, then the back sheet greatly curls and shrinks after 60 hours and is therefore deformed.

The invention has been made in consideration of the above, and the technical problem with the invention is to provide a solar cell protective sheet which is excellent in adhesiveness between the polyester support and the functional layer formed thereon by water-based coating and which can maintain a good shape when kept in a high-temperature high-humidity environment.

### Means for Solving the Problems

The inventors have assiduously studied for solving the above-mentioned problems and, as a result, have found that, when in place of the polymer support sheet having a thickness of 125 μm that is used in Examples in PATENT DOCUMENT 1, a polyester support having a thickness that falls within a specific range and is larger than that thickness of the polymer support sheet is used and when the thermal shrinkage of the polyester support before coated is controlled to fall within a specific range, then the adhesiveness between the polyester support and the functional layer could be improved and the coated sheet can keep a good shape when kept in high-temperature high-humidity environments.

The concrete measure of the invention for solving the above-mentioned problems includes the following:

[1] A solar cell protective sheet comprising:

a polyester support having a thickness of from 145 μm to 300 μm, a thermal shrinkage in an in-plane first direction after aged at 150° C. for 30 minutes of from 0.2 to 1.0% and a thermal shrinkage in a second direction perpendicular to the first direction of from −0.3 to 0.5%, and a polymer layer arranged on the polyester support and having a residual solvent amount of at most 0.1% by mass.

[2] Preferably, in the solar cell protective sheet of [1], the thickness of the polymer layer is at least 1 μm.
[3] Preferably, in the solar cell protective sheet of [1] or [2], the in-plane first direction of the polyester support is the film longitudinal direction.
[4] Preferably, in the solar cell protective sheet of any one of [1] to [3], the polyester support is a polyethylene terephthalate support.
[5] Preferably, in the solar cell protective sheet of any one of [1] to [4], the terminal carboxyl group content in the polyester support is at most 20 eq/t.
[6] Preferably, in the solar cell protective sheet of any one of [1] to [5], the peak of tan δ of the polyester support, as measured with a dynamic viscoelastometer, is at 123° C. or higher.
[7] Preferably, in the solar cell protective sheet of any one of [1] to [6], the intrinsic viscosity IV of the polyester support is at least 0.65 dl/g.
[8] Preferably, the solar cell protective sheet of any one of [1] to [7] has, as the polymer layer, a white layer containing a white pigment and a binder.
[9] Preferably, in the solar cell protective sheet of [8], the white layer is formed by coating.
[10] Preferably, in the solar cell protective sheet of [9], the white layer contains, as the binder, a water-based latex-derived binder.
[11] Preferably, in the solar cell protective sheet of any one of [8] to [10], the binder in the white layer is a copolymer containing an olefin component and at least any one of an acrylate component and an acid anhydride component.
[12] Preferably, the solar cell protective sheet of any one of [1] to [11] has, as the polymer layer, a weather-resistant layer containing at least one of a fluoropolymer and a silicone-acrylic composite resin.
[13] Preferably, in the solar cell protective sheet of [12], the weather-resistant layer is formed by coating.
[14] Preferably, in the solar cell protective sheet of [12] or [13], the fluoropolymer or the silicone-acrylic composite resin in the weather-resistant layer is a water-based latex-derived binder.
[15] Preferably, in the solar cell protective sheet of any one of [12] to [14], the weather-resistant layer is arranged in contact with the polyester support.
[16] Preferably, the solar cell protective sheet of any one of [12] to [15] has the white layer on one side of the polyester support and has the weather-resistant layer on the other side opposite to the side of the polyester support having the white layer thereon.
[17] Preferably, in the solar cell protective sheet of [16], the weather-resistant layer comprises a first weather-resistant layer containing a silicone-acrylic composite resin and, as arranged on the first weather-resistant layer, a second weather-resistant layer containing a fluoropolymer.
[18] A method for producing a solar cell protective sheet, comprising:

applying a polymer layer-forming coating liquid that comprises a solvent or a dispersion medium of which the main component is water, and a binder, onto a polyester support, wherein the polyester support has a thickness of from 145 μm to 300 μm, a thermal shrinkage in an in-plane first direction after aged at 150° C. for 30 minutes of from 0.2 to 1.0%, and a thermal shrinkage in a second direction perpendicular to the first direction of from −0.3 to 0.5%.

[19] Preferably, in the method for producing a solar cell protective sheet of [18], the polymer layer-forming coating liquid is applied so that the dry thickness of the polymer layer could be at least 1 μm.
[20] Preferably, in the method for producing a solar cell protective sheet of [18] or [19], the in-plane first direction of the polyester support is the film-conveying direction.
[21] Preferably, in the method for producing a solar cell protective sheet of any one of [18] to [20], the polyester support is a polyethylene terephthalate support.
[22] Preferably, in the method for producing a solar cell protective sheet of any one of [18] to [21], the terminal carboxyl group content in the polyester support is at most 20 eq/t.
[23] Preferably, in the method for producing a solar cell protective sheet of any one of [18] to [22], the peak of tan δ of the polyester support, as measured with a dynamic viscoelastometer, is at 123° C. or higher.
[24] Preferably, in the method for producing a solar cell protective sheet of any one of [18] to [23], the intrinsic viscosity IV of the polyester support is at least 0.65 dl/g.
[25] Preferably, the method for producing a solar cell protective sheet of any one of [18] to [24] comprises adding a white pigment to the polymer layer-forming coating liquid to prepare a white layer-forming coating liquid.
[26] Preferably, in the method for producing a solar cell protective sheet of [25], the binder in the white layer-forming coating liquid is a copolymer containing an olefin component and at least any one of an acrylate component and an acid anhydride component.
[27] Preferably, the method for producing a solar cell protective sheet of any one of [18] to [26] comprises using, as the binder, at least one of a fluoropolymer and a silicone-acrylic composite resin to prepare a weather-resistant layer-forming coating liquid.
[28] Preferably, the method for producing a solar cell protective sheet of anyone of [18] to [27] comprises using water as the dispersion medium and using a water-based binder as the binder, followed by dispersing the water-based binder in water to thereby prepare the polymer layer-forming coating liquid.
[29] Preferably, the method for producing a solar cell protective sheet of [27] or [28] includes applying the white layer-forming coating liquid onto one side of the polyester support, and applying the weather-resistant layer-forming liquid onto the other side opposite to the side of the polyester support coated with the white layer-forming coating liquid.
[30] Preferably, the method for producing a solar cell protective sheet of [29] comprises using, as the weather-resistant layer-forming coating liquid, a coating liquid that contains a silicone-acrylic composite resin to thereby form a first weather-resistant layer, and further applying, onto the first weather-resistant layer, a coating liquid that contains a fluoropolymer to thereby form a second weather-resistant layer.
[31] A solar cell back sheet provided with a solar cell protective sheet of any one of [1] to [17], or with a solar cell protective sheet produced according to the solar cell protective sheet production method of any one of [18] to [30].
[32] A solar cell module provided with the solar cell back sheet of [31].

### Advantageous Effects of the Invention

According to the configuration of the solar cell protective sheet of the invention, there is provided a solar cell protective sheet which is excellent in adhesiveness between the polyester support and the functional layer formed thereon by water-based coating and which can maintain a good shape when kept in a high-temperature high-humidity environment. According to the production method for the solar cell protective sheet of the invention, there is provided a solar cell protective sheet which is free from a problem of shape and adhesiveness change before and after moisture resistance testing since a thick support is used and coated.

### BRIEF DESCRIPTION OF DRAWINGS

FIG. 1 is a schematic view showing one example of the cross section of the solar cell protective sheet of the invention.

FIG. 2 is a schematic view showing one example of the cross section of a solar cell module using the solar cell protective sheet of the invention as the solar cell back sheet therein.

### MODE FOR CARRYING OUT THE INVENTION

The solar cell protective sheet of the invention (hereinafter this may be referred to as “solar cell protective sheet of the invention”) and its production method of the invention, and the solar cell back sheet and the solar cell module of the invention using the sheet are described in detail hereinunder.

The description of the constitutive elements of the invention given hereinunder is for some typical embodiments of the invention, to which, however, the invention should not be limited. In this description, the numerical range expressed by the wording “a number to another number” means the range that falls between the former number indicating the lowermost limit of the range and the latter number indicating the uppermost limit thereof.

### [Solar Cell Protective Sheet]

The solar cell protective sheet of the invention comprises a polyester support of which the thickness is from 145 μm to 300 μm, of which the thermal shrinkage in an in-plane first direction after aged at 150° C. for 30 minutes is from 0.2 to 1.0% and of which the thermal shrinkage in a second direction perpendicular to the first direction is from −0.3 to 0.5%, and a polymer layer arranged on the polyester support and having a residual solvent amount of at most 0.1% by mass. In the solar cell protective sheet of the invention, the in-plane first direction of the polyester support is preferably the film longitudinal direction.

If desired, the solar cell protective sheet of the invention may be so configured as to have any additional layer such as an easy-adhesion layer or the like to enhance the adhesiveness to the battery-side substrate (for example, sealant such as EVA, etc.) (for example, to increase the adhesion force to the sealant to 10 N/cm or more).

One more preferred embodiment of the solar cell protective sheet of the invention is that the sheet has a high adhesion force even after wet heat aging and additionally has a high fracture elongation retention (retention of fracture elongation). In the case, preferably, the fracture elongation retention in 105 hours at 120° C. and at a relative humidity of 100% is at least 50%, more preferably at least 65%, even more preferably at least 80%. Here, “fracture elongation retention” means the ratio of the fracture elongation (Lt) after thermal treatment to the fracture elongation (Li) before thermal treatment, and is expressed by the following equation. One sample is measured both in MD and TD, and the found data are averaged to give the mean value of the intended fracture elongation retention.

Fracture Elongation Retention (%)=100×(Lt)/(Li)

The solar cell protective sheet of the invention has a polymer layer that has a residual solvent amount of at most 0.1% by mass. Preferably, the total residual solvent amount contained in the entire solar cell protective sheet is also at most 0.1% by mass, more preferably at most 0.05% by mass, even more preferably at most 0.01% by mass.

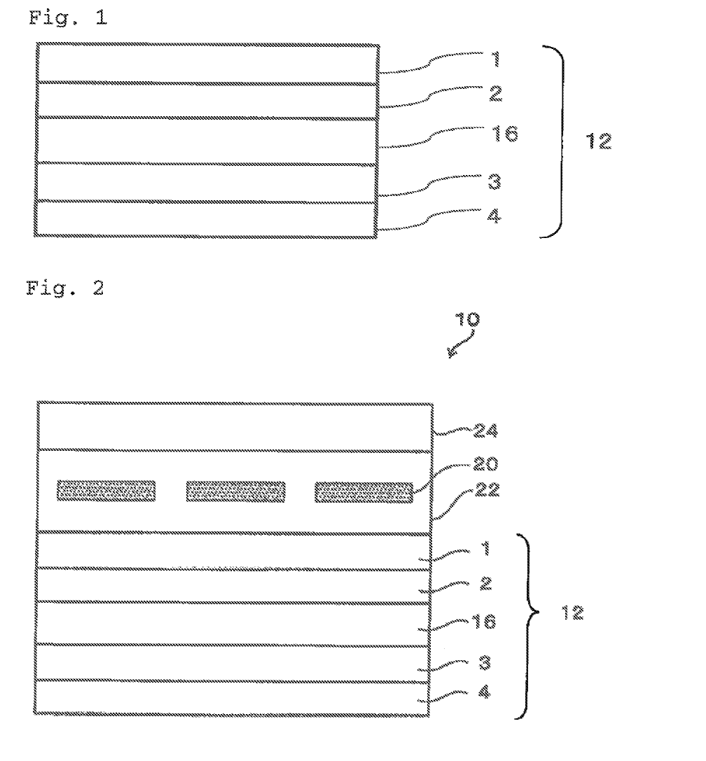

First, one preferred configuration of the solar cell protective sheet of the invention is shown in FIG. 1. In the polymer sheet shown in FIG. 1, a polymer layer 3 is arranged on one side of a polyester support 16, and a polymer layer 1 is arranged on the other side of the support. In addition, any further additional two or more polymer layers may be arranged in the sheet.

The details of preferred embodiments of each layer constituting the polymer sheet of the invention are described below.

### (Polyester Support)

In the solar cell protective sheet of the invention, the thickness of the polyester support is from 145 μm to 300 μm.

In the prior art described in Examples in JP-A 2010-519742, used is a 125-μm PET film, and therefore the time degradation of the hydrolysis resistance of the film is significant. The polyester support for use in the invention has a thickness falling within a specific range, and therefore the mechanical characteristic change thereof before and after moisture resistance testing is small. In addition, it is desirable that the change in the dielectric breakdown strength of the support before and after moisture resistance testing is also small.

In the invention, more preferably, the thickness of the polyester support is from 180 μm to 270 μm, even more preferably from 210 μm to 250 μm, from the viewpoint of more favorably exhibiting the effect of improving the wet heat resistance of the adhesiveness of the support.

Recently, not only increasing the output power of solar cells but also improving the electric insulating capability of solar cell back sheets has become desired. In general, the electric insulation of back sheets is proportional to the thickness thereof, and therefore thicker back sheets are desired. Regarding this, when the thickness of the polyester support is controlled to fall within the above-mentioned preferred range here, there could be provided a solar cell protective sheet additionally having a good electric insulating capability.

In the solar cell protective sheet of the invention, the thermal shrinkage of the polyester support in an in-plane first direction after aged at 150° C. for 30 minutes is from 0.2 to 1.0% and the thermal shrinkage thereof in a second direction perpendicular to the first direction is from to 0.5%. In particular, it is desirable that the thermal shrinkage of the polyester support before coated with the polymer layer to be mentioned below falls within the range from the viewpoint of improving the adhesiveness thereof after wet heat aging. Not adhering to any theory, it is considered that the adhesion between the polyester support and the coating layer thereon would result from the residual stress in the interface between the polyester support and the coating layer. The residual stress in the interface between the polyester support and the coating layer is defined by the balance between the expansion force or the contraction force of the polyester support and the expansion force and the contraction force of the coating layer. In the solar cell protective sheet of the invention, the thickness of the polyester support is large, and therefore the influence of the expansion force/contraction force of the polyester support on the residual stress in the interface between the polyester support and the coating layer is great. Consequently, when the thermal shrinkage of the polyester support in the in-plane first direction thereof after aged at 150° C. for 30 minutes is controlled to be at least 0.2%, then the influence of the thermal expansion of the polyester support on the adhesiveness thereof to the coating layer could be greatly improved as compared with any other case where a polyester support having a smaller thermal shrinkage of less than 0.2% is used. In addition, when the thermal shrinkage in the in-plane first direction is controlled to be at most 1.0%, then the thermal shrinkage of the polyester support is not too large and the adhesiveness thereof to the coating layer could be thereby improved.

The influence is more remarkable when the thickness of the polyester support is from 10 to 40 times the thickness of the polymer layer (coating layer) to be mentioned below.

Preferably, the first direction is the film longitudinal direction, and for example, the first direction is preferably the film conveying direction in producing the polyester support (hereinafter this may be referred to as machine direction, MD). On the other hand, the second direction is preferably the film widthwise direction, and for example, the second direction is preferably the direction perpendicular to the film conveying direction in producing the polyester support (hereinafter this may be referred to as transverse direction, TD).

Preferably, the thermal shrinkage in the first direction (preferably MD) is from 0.3 to 0.8%, more preferably from 0.4 to 0.7%. On the other hand, the thermal shrinkage in the second direction (preferably TD) is from to 0.5%, more preferably from 0.0 to 0.5%.

The in-plane thermal shrinkage of the polyester after aged at 150° C. for 30 minutes may be controlled by the film formation condition (stretching condition in film formation, especially thermal relaxation condition after stretching).

In general, when the molecular weight of the polyester support is large, then the thermal shrinkage thereof is large, and would be, for example, 2% or so. As described below, in producing the polyester support in one preferred embodiment of the invention, the polyester is produced through solid-phase polymerization so as to have an increased molecular weight (IV), and further, the terminal carboxyl group content AV in the polyester is reduced to be at most 20 eq/t, and in addition, the polyester support is formed so as to satisfy the above-mentioned thermal shrinkage condition. Heretofore, no one knows such a polyester support capable of satisfying all the requirements of low thermal shrinkage, high IV and low terminal carboxyl group content AV.

The polyester support may be a filmy or sheet-like one. The solar cell protective sheet of the invention uses the polyester support from the viewpoint of the cost and the mechanical strength thereof.

The polyester substrate for use as the polyester support in the invention is a linear saturated polyester to be synthesized from an aromatic dibasic acid or its ester-forming derivative and a diol or its ester-forming derivative. Specific examples of the polyester include films or sheets of polyethylene terephthalate, polyethylene isophthalate, polybutylene terephthalate, poly(1,4-cyclohexylenedimethylene terephthalate), polyethylene-2,6-naphthalate or the like. Of those, especially preferred are polyethylene terephthalate and polyethylene-2,6-naphthalate from the viewpoint of the balance between the mechanical properties and the cost thereof.

The polyester substrate may be a homopolymer or a copolymer. Further, the substrate may be a blend of a polyester with a small amount of any other type of resin, for example, polyimide, etc.

In producing the polyester for use in the invention, preferably used is an Sb-containing, Ge-containing or Ti-containing compound as the catalyst, from the viewpoint of controlling the carboxyl group content in the polyester to fall within a predetermined range. Especially preferred is use of a Ti-containing compound. In the preferred embodiment of polymerization using a Ti-containing compound, it is desirable that the Ti-containing compound is used as the catalyst in an amount of from 1 ppm to 30 ppm, more preferably from 3 ppm to 15 ppm as the Ti element-equivalent amount. When the Ti element-equivalent amount of the Ti-containing compound to be used falls within the above range, then it is possible to control the terminal carboxyl group content to fall within the range mentioned below, and it is also possible to keep the hydrolysis resistance of the polyester support low.

In producing the polyester with a Ti-containing compound, for example, usable are the methods described in JP-B 8-301198, Japanese Patents 2543624, 3335683, 3717380, 3897756, 3962226, 3979866, 3996871, 4000867, 4053837, 4127119, 4134710, 4159154, 4269704, 4313538, etc.

In the solar cell protective sheet of the invention, preferably, the terminal carboxyl group content AV in the polyester support is at most 20 eq/t (ton—the same shall apply hereinunder), from the viewpoint of increasing the hydrolysis resistance of the support and of preventing the strength of the support from lowering in wet heat aging. More preferably the content is from 5 to 18 eq/t, even more preferably from 9 to 17 eq/t.

The carboxyl group content in the polyester could be controlled by the type of the polymerization catalyst before film formation and the solid-phase polymerization condition after ordinary polymerization, and also by the film formation condition (film formation temperature and time, stretching condition and heat relaxation condition), etc. In particular, it is desirable that the content is controlled by the solid-phase polymerization condition before formation of the polyester support in the form of a film. Preferably, the terminal carboxyl group content in the starting polyester after solid-phase polymerization and before formation into a film-shaped polyester support is from 1 to 20 eq/t, more preferably from 3 to 18 eq/t, even more preferably from 6 to 14 eq/t.

The carboxyl group content (AV) could be measured according to the method described in H. A. Pohl, Anal. Chem. 26 (1954) 2145. Concretely, the intended polyester is ground into powder and then dried in a vacuum drier at 60° C. for 30 minutes. Next, immediately after the drying, 0.1000 g of the polyester is metered, 5 ml of benzyl alcohol is added thereto, and stirred with heating for dissolution at 205° C. for 2 minutes. The solution is cooled, then 15 ml of chloroform is added thereto, and using phenol red as an indicator, the sample is titered with an alkali standard liquid (0.01 N KOH-benzyl alcohol mixed solution) to the neutralization point (pH=7.3±0.1). From the titered data, the content is calculated.

Also preferably, in the solar cell protective sheet of the invention, the intrinsic viscosity IV (molecular weight) of the polyester support is at least 0.65 dl/g, more preferably from 0.68 to 0.85 dl/g, even more preferably from 0.70 to 0.80 dl/g.

The intrinsic viscosity IV of the polyester could be controlled by the type of the polymerization catalyst and the film formation condition (film formation temperature and time). In particular, it is desirable that the intrinsic viscosity is controlled by the solid-phase polymerization condition before formation of the film-like polyester support. Especially preferably, the intrinsic viscosity IV of the starting polyester before formation thereof into a film-like polyester support is from 0.68 to 0.90 dl/g, more preferably from 0.70 to 0.85 dl/g, even more preferably from 0.72 to 0.83 g/dl.

The IV value may be measured as follows: The intended polyester is ground into powder, and dissolved in a mixed solvent of 1,2,2-tetrachloroethane/phenol (=⅔ [ratio by mass]) to be 0.01 g/ml, and using an Ubbelohde viscometer (AVL-6C, by Asahi Kasei Technosystems), the sample is measured at a temperature of 25° C. The sample dissolution takes 15 to 30 minutes at 120° C.

Preferably, in the solar cell protective sheet of the invention, the peak of tan δ of the polyester support, as measured with a dynamic viscoelastometer, is at 123° C. or higher, more preferably at from 123 to 130° C., even more preferably at from 124 to 128° C.

The peak of tan δ of the polyester support could be controlled by the type of the polymerization catalyst before film formation and the solid-phase polymerization condition after ordinary polymerization, and also by the film formation condition (film formation temperature and time, stretching condition and heat relaxation condition), etc. In particular, it is desirable to control the data by the stretching conditions (stretching draw ratio and thermal fixation temperature) that could be controlled online.

The peak of tan δ is measured as follows: After conditioned at 25° C. and at a relative humidity of 60% for 2 hours or more, the sample is analyzed with a commercially-available dynamic viscoelastometer (Vibron: DVA-225 (by ITK)) at a heating speed of 2° C./min within a measurement temperature range of from 30° C. to 200° C. and at a frequency of 1 Hz.

Preferably, the polyester support is one subjected to solid-phase polymerization after polymerization. This could readily result in the preferred carboxyl group content and the preferred intrinsic viscosity of the polyester. The solid-phase polymerization may be in a continuous method (where the resin is filled in a tower, then gradually circulated therein with heating for a predetermined period of time and then discharged) or in a batch method (where the resin is put into a container and heated therein for a predetermined period of time). Concretely, the methods described in Japanese Patents 2621563, 3121876, 3136774, 3603585, 3616522, 3617340, 3680523, 3717392 and 4167159 may be applied to the solid-phase polymerization here.

The temperature of the solid-phase polymerization is preferably from 170° C. to 240° C., more preferably from 180° C. to 230° C., even more preferably from 190° C. to 220° C. The time of the solid-phase polymerization is preferably from 5 hours to 100 hours, more preferably from 10 hours to 75 hours, even more preferably from 15 hours to 50 hours. Preferably, the solid-phase polymerization is carried out in vacuum or in a nitrogen atmosphere.

Preferably, the polyester support in the invention is a biaxially-stretched film that is prepared by melt-extruding the above-mentioned polyester into a film, then cooling and solidifying the film on a casting drum to be an unstretched film, stretching the unstretched film at Tg to (Tg+60)° C. in the machine direction once or more to a total draw ratio of from 3 times to 6 times, and thereafter further stretching it in the cross direction at Tg to (Tg+60)° C. to a draw ratio of from 3 to 5 times.

Further, preferably in film formation thereof, the polyester support for use in the invention is heat-treated after stretched from the viewpoint of improving the hydrolysis resistance thereof and controlling the thermal shrinkage thereof. Preferably, the heat treatment is at from 150 to 230° C., more preferably from 180 to 225° C., even more preferably from 190 to 215° C. Also preferably, the heat treatment time is from 5 to 60 seconds, more preferably from 10 to 40 seconds, even more preferably from 10 to 30 seconds.

Preferably, in film formation thereof, the polyester support for use in the invention is thermally relaxed after stretched from the viewpoint of controlling the thermal shrinkage thereof. Preferably, the thermal relaxation is from 1 to 10% in MD, more preferably from 3 to 7%, even more preferably from 4 to 6%. Also preferably, the thermal relaxation is from 3 to 20% in TD, more preferably from 6 to 16%, even more preferably from 8 to 13%.

The thermal relaxation ratio in MD and TD may be independently controlled by using a simultaneous double-screw stretcher or by the use of an MD-contractible TD stretcher. Consequently, the thermal shrinkage of the polyester support may be so controlled as to fall within a different range in the first direction and in the second direction.

Inorganic fine particles may be added to the polyester support for the purpose of improving the reflectivity of the support.

Preferred inorganic fine particles for use herein include, for example, wet silica, dry silica, colloidal silica, calcium carbonate, aluminium silicate, calcium phosphate, alumina, magnesium carbonate, zinc carbonate, titanium oxide, zinc oxide (zinc flower), antimony oxide, cerium oxide, zirconium oxide, tin oxide, lanthanum oxide, magnesium oxide, barium carbonate, zinc carbonate, basic lead carbonate (lead white), barium sulfate, calcium sulfate, lead sulfate, zinc sulfide, mica, titanated mica, talc, clay, kaolin, lithium fluoride, calcium fluoride, etc. Of those inorganic fine powders, preferred are titanium dioxide and barium sulfate, and more preferred is titanium dioxide. Titanium oxide may be any of an anatase-type one or a rutile-type one, but preferred is a rutile-type one having a low photocatalyst activity. Titanium dioxide fine particles may be surface-treated with an inorganic substance such as alumina, silica or the like, or may be surface-treated with an organic substance such as a silicone material, an alcohol material or the like.

Any known method may be employed for adding inorganic fine particles to the polyester support. For example, when the polyester support is a polyethylene terephthalate support, typical methods for the supports are: (a) a method of adding inorganic fine particles before the end of the interesterification or esterification reaction in polyethylene terephthalate production, or adding inorganic fine particles before the start of polycondensation reaction; (b) a method of adding fine particles to polyethylene terephthalate followed by melt-kneading them; (c) a method comprising preparing master pellets to which a large amount of inorganic fine particles have been added thereto according to the above method (a) or (b) (hereinafter this may be referred to as master batch (MB)), followed by kneading them with polyethylene terephthalate not containing inorganic fine particles to thereby make the resulting batch contain a predetermined amount of inorganic fine particles; (d) a method of using the master pellets in the above (c) directly as they are.

Of those, preferred is the master batch method (MB method, the above (c)) in which polyester resin is previously mixed with inorganic fine particles in an extruder. Also employable here is another method comprising putting polyester resin and fine particles not previously dried, into an extruder and preparing MB therein with removing moisture and air through degassing. More preferably, MB is prepared by using a polyester resin that has been previously dried as much as possible, since the acid value of polyester could be prevented from increasing. In this case, there may be employed a method of extruding the mixture with degassing, or a method of extruding the mixture by using a fully-dried polyester resin with no degassification.

When inorganic fine particles are added, the mean particle size of the inorganic fine particles is preferably from 0.05 to 5 μm, more preferably from 0.1 to 3 μm, even more preferably from 0.15 to 0.8 μm. When the mean particle size is less than 0.05 μm, then the support could not enjoy sufficient reflectivity increase; but when more than 5 μm, then unfavorably, the mechanical strength of the support would be apparently lowered.

The content of the inorganic fine particles is preferably from 2 to 50% by mass relative to the total mass of the polyester support, more preferably from 5 to 20% by mass. When the content is less than 2% by mass, then the support could not enjoy sufficient reflectivity increase; but when more than 50% by mass, then unfavorably, the mechanical strength of the support would be apparently lowered.

In the polyester support of the invention, the content of the inorganic fine particles therein may be constant in the thickness direction, or the support may be composed of two or more layers each having a different inorganic fine particle content. In the latter case, preferred is a three-layer configuration where a layer having a high inorganic fine particle content exists inside the polyester support and both surface layers each have a low inorganic fine particle content, from the viewpoint of the durability of the support; and more preferably, the layers having a low inorganic fine particle content do not contain inorganic fine particles.

Preferably, a terminal blocking agent is added to the polyester support, or that is, it is desirable that the polyester support contains a terminal blocking agent. The terminal blocking agent as referred to in the invention is a compound capable of reacting with the terminal carboxylic acid of the polyester support, acting for improving the hydrolysis resistance of the polyester support. Hydrolysis of the polyester support is accelerated by the catalytic effect of that is given by the terminal carboxylic acid or the like in the support, and therefore it is considered that the formation of H⁺ could be prevented by the terminal blocking agent to thereby improve the hydrolysis resistance of the support.

Specific examples of the terminal blocking agent include epoxy compounds, carbodiimide compounds (carbodiimide-type terminal blocking agents), oxazoline compounds, carbonate compounds, etc. Preferred are carbodiimides having a high affinity for PET and having a high terminal blocking capability.

Of carbodiimide compounds, preferred are those having a cyclic structure (for example, those described in JP-A 2011-153209). The terminal carboxylic acid of polyester reacts with a cyclic carbodiimide in a mode of ring-opening reaction, and one of the ring-opened product reacts with the polyester while the other thereof reacts with another polyester thereby providing a product having an increased molecular weight and preventing generation of isocyanate gas.

Specific examples of the carbodiimide compounds include dicyclohexylcarbodiimide, diisopropylcarbodiimide, dimethylcarbodiimide, 1,5-naphthalenecarbodiimide, 4,4′-diphenylmethanecarbodiimide, 4,4′-diphenyldimethylmethanecarbodiimide, cyclic structure-having carbodiimides described in JP-A 2011-153209, etc.

Preferably, the molecular weight of the terminal blocking agent is from 200 to 100,000, more preferably from 2000 to 80,000, even more preferably from 10,000 to 50,000. When the molecular weight of the terminal blocking agent is more than 100,000, then the agent is difficult to disperse uniformly in polyester so that it is difficult for the agent to sufficiently exhibit the effect of improving weather resistance. On the other hand, when the molecular weight is less than 200, then the agent would readily evaporate away during extrusion and film formation and, unfavorably, therefore, it is difficult for the agent to sufficiently exhibit the effect of improving weather resistance.

The amount of the terminal blocking agent to be added is preferably from 0.1 to 10% by mass relative to polyester, more preferably from 0.2 to 5% by mass, even more preferably from 0.3 to 2% by mass. When the amount is less than 0.1% by mass, then a sufficient effect of improving weather resistance could not be attained, and when more than 10% by mass, then aggregates may form in the process of producing the polyester support.

Preferably, the polyester support is surface-treated in any mode of corona treatment, flame treatment, low-pressure plasma treatment, atmospheric pressure plasma treatment, or UV treatment. Such surface treatment given to the surface of support to be coated but before coated with a polymer layer thereon may further enhance the adhesiveness of the support to the coating layer in exposure to wet heat environments. In particular, corona treatment is preferred as providing a more excellent effect of adhesiveness improvement.

The surface treatment increases the carboxyl groups and the hydroxyl groups existing in the surface of the polyester support (for example, polyester substrate), whereby the adhesiveness of the polyester support to the coating layer could be enhanced. When the surface treatment is combined with use of a crosslinking agent (especially an oxazoline-type or carbodiimide-type crosslinking agent having high reactivity with carboxyl group), then more powerful adhesiveness could be obtained. This is more remarkable in corona treatment. Accordingly, it is desirable that the surface of the polyester support to be coated with a polymer layer is corona-treated.

In the invention, the corona treatment may be carried out as follows: In general, high-frequency high-voltage discharge is applied between electrodes electrically insulated from a dielectric-coated metal roll (dielectric roll) to thereby generate air insulation breakdown between the electrodes, by which air between the electrodes is ionized to generate corona discharge between the electrodes. In the situation, the support to be processed is led to run through the space with corona discharge.

Preferred treatment conditions in the invention are: gap clearance between the electrode and the dielectric roll, 1 to 3 mm; frequency, 1 to 100 kHz; energy application, 0.2 to 5 kV·A·min/m² or so.

Prior to the corona treatment in the invention, preferably, the film to be treated is previously heated. According to the method, better adhesiveness could be obtained within a shorter period of time than in the case where the film is not heated. The heating temperature is preferably within a range of from 40° C. to the softening point of the film to be treated+20° C., more preferably within a range of from 70° C. to the softening point of the film to be treated. When the heating temperature is not lower than 40° C., then a sufficient effect of adhesiveness improvement could be obtained. When the heating temperature is not higher than the softening temperature of the film to be treated, then good handleability of the film during the treatment could be secured.

A concrete method of increasing the film to be treated in vacuum comprises heating the film with an IR heater, or heating the film through contact with a hot roll, etc.

As the surface treatment method for use in the invention, also preferred is a method of low-pressure plasma treatment. Preferably, at least one surface of the two surfaces of the polyester support is processed through low-pressure plasma treatment, and more preferably, at least the surface of the white layer side to be mentioned below of the support is processed through low-pressure plasma treatment.

Low-pressure plasma treatment is referred to as a method of vacuum plasma treatment or glow discharge treatment, in which plasma is generated through discharge in a vapor of a low-pressure atmosphere (plasma gas) to thereby treat the surface of the substrate. Low-pressure plasma for use in the invention is preferably non-equilibrium plasma to form at a low plasma gas pressure. In the invention, the surface treatment may be carried out by arranging the film to be treated in such a low-pressure plasma atmosphere.

As the method of generating plasma for the low-pressure plasma treatment in the invention, there may be employed a method of direct current glow discharge, high-frequency discharge, microwave discharge, etc. The power for use for the discharge may be a direct current or an alternate current. When an alternate current is used, preferably it falls within a range of from 30 Hz to 20 MHz or so.

In case where an alternate current is used, a commercially-available frequency of 50 or 60 Hz may be used, or a high frequency of from 10 to 50 kHz or so may be used. Also preferred is a method of using a high frequency of 13.56 MHz.

As the plasma gas for use for the low-pressure plasma treatment in the invention, employable is an inorganic gas such as oxygen gas, nitrogen gas, steam gas, argon gas, helium gas, etc. Especially preferred is oxygen gas or a mixed gas of oxygen gas and argon gas. Concretely, it is desirable to use a mixed gas of oxygen gas and argon gas. In case where oxygen gas and argon gas are used, the ratio of the two is, as the partial pressure ratio thereof, preferably oxygen gas/argon gas=100/0 to 30/70 or so, more preferably 90/10 to 70/30 or so. Also preferred is a method where no vapor is introduced into the treatment container and the vapor that results from air to come in the treatment container through leakage or results from the material to be treated therein, such as water vapor or the like is used as the plasma gas.

The plasma gas pressure must be a low pressure capable of achieving a non-equilibrium plasma condition. Concretely, the plasma gas pressure is preferably within a range of from 0.005 to 5 Torr, more preferably from 0.05 to 1 Torr, even more preferably from 0.08 to 0.8 Torr. When the plasma gas pressure is lower than 0.005 Torr, then the effect of adhesion improvement may be insufficient, but on the contrary, when higher than 10 Torr, then the current may increase so that the discharge would be unstable.

Varying depending on the shape and the size of the treatment container and on the shape of the electrode, the plasma output power could not be indiscriminately defined, but is preferably from 100 to 25000 W or so, more preferably from 500 to 15000 W or so.

The processing time for the low-pressure plasma treatment is preferably from 0.05 to 100 seconds, more preferably from 0.5 to 30 seconds or so. When the processing time is shorter than 0.05 seconds, then the effect of adhesiveness improvement may be insufficient, but on the contrary, when longer than 100 seconds, there may occur some problems of deformation or discoloration of the treated films.

The discharge treatment intensity in the low-pressure plasma treatment in the invention may vary depending on the plasma output power and the processing time, but is preferably within a range of from 0.01 to 10 kV·A·min/m², more preferably from 0.1 to 7 kV·A·min/m². When the discharge treatment intensity is at least 0.01 kV·A·min/m², then the treatment provides a sufficient effect of adhesiveness improvement, and when at most 10 kV·A·min/m², then the treatment may be free from risks of deformation or discoloration of the treated films.

Also prior to the low-pressure plasma treatment in the invention, it is desirable that the film to be treated is previously heated. According to the method, better adhesiveness may be obtained within a shorter period of time than in the case with no preheating. Regarding the heating temperature and the heating methods, referred to are the temperature range and the method described in the section of corona treatment.

### (Polymer Layer)

The solar cell protective sheet of the invention has a polymer layer having a residual solvent amount of at most 0.1% by mass. The polymer layer may be formed by water-based coating. Preferably, the residual solvent amount in the polymer layer is at most 0.05% by mass, more preferably at most 0.01% by mass. The method of measuring the residual solvent amount in the polymer layer is not specifically defined. The other layers than the polymer layer to be analyzed are previously removed, and then the polymer layer is analyzed to measure the residual solvent amount therein.

The polymer layer in the solar cell protective sheet of the invention is a layer that is arranged in contact with the surface of the polyester support either directly thereto or via any other layer therebetween.

The polymer layer in the invention is improved in point of the adhesiveness thereof to the adjacent material of the polyester support or the like. The solar cell protective sheet of the invention is produced by forming the polymer layer having a residual solvent amount of at most 0.1% by mass by water-based coating, and therefore, as a preferred embodiment of the case, it is desirable that the polymer layer does not have an adhesive layer between the polymer layer and the polyester support, and the preferred embodiment of the polymer layer is except the other embodiment where the polymer layer is bonded to the surface of the polyester support by thermal compression bonding.

If desired, the polymer layer may comprise any other component. Depending on the applicable use, the constituent components may vary. Preferably, the polymer layer is so configured as to additionally play another role of coloration layer for providing sunlight reflectivity or outward appearance design (especially preferably, the layer is a white layer that plays a role of light reflectivity). In case where the polymer layer is so configured as to be a light-reflective layer capable of reflecting sunlight toward the incident side, it is desirable that the solar cell protective sheet of the invention has, as the polymer layer, a white layer that contains a white pigment.

Also preferably, the polymer layer is formed as a back layer to be arranged on the side opposite to the side of the polyester support on which sunlight falls. In case where the polymer layer is arranged as the back layer serving as a weather-resistant layer, the solar cell protective sheet of the invention preferably has, as the polymer layer, a weather-resistant layer containing at least one of a fluoropolymer and a silicone-acrylic composite resin.

Depending on the function of the polymer layer, the preferred thickness of the polymer layer may vary. Preferably, in the solar cell protective sheet of the invention, the thickness of the polymer layer is at least 1 μm, more preferably at least 2 μm, even more preferably from 5 to 15 μm.

Various components constituting the polymer layer are described below along with the function of the polymer layer.

Polymer Layer as White Layer

In case where the polymer layer in the invention serves as a white layer (light-reflective layer), the polymer layer in the invention contains a white pigment. If desired, the white layer may additionally contain any other components such as various types of additives. Preferably, the peeling force from a sealant material is at least 5 N/cm.

One function of the white layer is to increase the power generation efficiency of a solar cell module by bringing the moiety of the incident light having passed through the solar cell and having reached the back sheet without being used for power generation, back to the solar cell.

Polymer

Preferably, at least one polymer selected from a polyolefin resin, an acrylic resin and a polyvinyl alcohol resin is used as the binder in the white layer, from the viewpoint of increasing the adhesiveness of the polymer layer to EVA or the like used as a sealant in solar cell modules, to at least 5 N/cm. Above all, from the viewpoint of durability, preferred are acrylic resin and polyolefin.

The polyolefin resin is preferably a resin containing an olefin component in an amount of at least 50 mol %. Preferably, the polyolefin resin is a copolymer containing at least one of an acrylic component and a carboxylic acid component, and an olefin component. In the solar cell protective sheet of the invention, preferably, the binder for use in the white layer is a copolymer containing an olefin component and at least any one of an acrylate component and an acid anhydride component (so-called modified olefin copolymer).

As preferred examples of the olefin component to constitute the polyolefin resin, there are mentioned ethylene, propylene, etc. These may be used either singly or as a mixture of different types of those components.

Preferred examples of the carboxylic acid component to constitute the polyolefin resin include acrylic acid, methacrylic acid, itaconic acid, maleic acid, maleic acid anhydride, etc. These may be used either singly or as a mixture of different types of those components.

Preferably, the polyolefin resin additionally contains a so-called acrylic component or an ester component thereof, as further copolymerized with an acrylic monomer or a methacrylic monomer, in addition to the carboxylic acid component. Especially preferably, the polyolefin resin contains an acrylate component. Specific examples of acrylic monomers or methacrylic monomers include methyl methacrylate, ethyl acrylate, butyl acrylate, 2-hydroxyethyl acrylate, etc.

The total amount of the olefin component (ethylene, propylene, etc.) in the polyolefin resin is preferably within a range of from 70 to 98 mol %, more preferably from 80 to 96 mol %. The total amount of the acrylic component (acrylic monomer, methacrylic monomer, etc.) is preferably within a range of from 0 to 20 mol %, more preferably from 3 to 10 mol %. The total amount of the carboxylic acid component is preferably from 0 to 15 mol %, more preferably from 0.2 to 10 mol %. Of those polymers, especially preferred is a polymer containing ethylene or propylene in an amount of from 70 to 98 mol %, acrylic acid or methacrylic acid in an amount of from 0.1 to 15 mol %, and a monomer selected from methyl acrylate, methyl methacrylate, ethyl acrylate and butyl acrylate in an amount of from 0.1 to 20 mol %; and even more preferred is a polymer containing ethylene or propylene in an amount of from 80 to 96 mol %, acrylic acid or methacrylic acid in an amount of from 0.1 to 10 mol %, and a monomer selected from methyl acrylate, methyl methacrylate, ethyl acrylate and butyl acrylate in an amount of from 3 to 10 mol %.

Having a monomer composition that falls within the above-mentioned range, the polymer layer can satisfy both good adhesiveness and good durability.

Preferably, the molecular weight of the polyolefin resin for use in the invention is from 2000 to 200000 or so. The polyolefin resin may have a linear structure or a branched structure.

As the polyolefin resin in the invention, usable are commercially-available ones, including, for example, Arrow Base SE-1013N, SD-1010, TC-4010, TD-4010 (all by Unitika), Hitec S3148, S3121, S8512 (all by Toho Chemical), Chemipearl S-120, S-75N, V100, EV210H (all by Mitsui Chemical), etc. Of those, preferred is use of Arrow Base SE-1013N (by Unitika).

As the acrylic resin, for example, preferred is a polymer containing polymethyl methacrylate, polymethyl methacrylate, etc. As the acrylic resin, usable here are commercially-available ones, including, for example, AS-563A (by Daicel FineChem).

More preferably, the white layer contains, as the binder, therein, a water-based latex-derived binder.

Examples of the other preferred binders are mentioned. Specific examples of polyolefins include Chemipearl S-120, S-75N (both by Mitsui Chemical); and specific examples of acrylic resins include Jurymer ET410, SEK-301 (both by Nippon Pure Chemicals), etc.

Of those, from the viewpoint of securing the adhesiveness between the polyester support and the first polymer layer, it is desirable that an acrylic resin or a polyolefin resin is used in the second polymer layer. In particular, preferred is use of a polyolefin resin, and more preferred is use of a polyolefin resin of a copolymer containing at least any one of an acrylic component and a carboxylic acid component and an olefin component in which the olefin component accounts for from 70 to 98 mol %.

Two or more different types of such polymers may be used here as combined, and in this case, preferred is a combination of an acrylic resin and a polyolefin resin.

The content of the binder in the white layer is preferably within a range of from 0.05 to 5 g/m², and more preferably within a range of from 0.08 to 3 g/m². When the binder content is at least 0.05 g/m², then the desired adhesion force could easily be obtained, and when at most 5 g/m², then a better surface condition could be obtained.

Preferably, the adhesiveness of the white layer to EVA used as a sealant in a solar cell module is at least 5 N/cm, more preferably more than 30 N/cm, and even more preferably from 50 to 150 N/cm.

White Pigment

The white layer in the invention may contain at least one white pigment.

As the white pigment, preferred is an inorganic pigment such as titanium dioxide, barium sulfate, silicon oxide, aluminium oxide, magnesium oxide, calcium carbonate, kaolin, talc, colloidal silica or the like, or an organic pigment such as hollow particles, etc.

Preferably, in the polymer sheet of the invention, the volume fraction of the pigment in the white layer is from 15 to 50%, more preferably from 18 to 30%, even more preferably from 20 to 25%. When the volume fraction of the pigment in the white layer is at least 15%, then a good surface condition could be obtained and a sufficient reflectivity could be obtained. On the other hand, when the volume fraction of the pigment in the white layer is at most 50%, then there may hardly occur a risk of cohesive failure owing to poor strength of the white layer, and in addition, the adhesiveness between the white layer and the sealant and also the adhesiveness between the white layer and the undercoat layer could be kept good during the time before and after wet heat aging, and therefore the range is preferred. In general, in the range where the volume fraction of the pigment in the white layer is at most 50%, the white layer is brittle and therefore the layer may peel. However, having the configuration of the invention, even though the white layer having the white pigment volume fraction of 50% is brittle, the adhesiveness of the white layer to the sealant and the undercoat layer to be mentioned below in a solar cell module could be kept good.

The pigment volume fraction in the polymer layer may be calculated according to the following formula.

Pigment Volume Fraction (%)=(pigment volume)/(binder volume+pigment volume)

The volume of the pigment and the binder may be obtained by measurement, or the pigment volume may be calculated from pigment mass/pigment specific gravity, and the binder volume may be calculated from binder mass/binder specific gravity.

The content of the pigment in the white layer is preferably within a range of from 3 to 18 g/m², more preferably from 3.5 to 15 g/m², even more preferably from 4.5 to 10 g/m². When the pigment content is at least 3.0 g/m², then the necessary coloration could be obtained and the layer can effectively provide reflectivity and decorative appearance. In addition, when the pigment content in the white layer is at most 18 g/m², then the surface condition of the white layer could be kept good with ease and the film strength could be more excellent.

Preferably, the mean particle size of the pigment is from 0.03 to 0.8 μm as the volume-average particle size thereof, more preferably from 0.15 to 0.5 μm or so. When the mean particle size falls within the range, then the light reflectivity of the layer could be high. The mean particle size is a value measured with a laser analyzing/scattering particle sizer LA950 (by Horiba Seisakusho).

In case where the white layer is provided as the polymer layer, it is desirable that the light reflectivity at 550 nm on the surface on the side on which the white layer is arranged (outermost surface) is at least 75%, more preferably at least 80%. Here the light reflectivity is as follows: In a case where the polymer sheet of the invention is used as a solar cell back sheet and when the incident light toward the sealant side of a solar cell module is reflected on the white layer and again goes out from the sealant side of the solar cell module, the ratio of the amount of the incident light to the amount of the outgoing light indicates the light reflectivity. Here, alight having a wavelength of 550 nm is sued as a typical wavelength light.

When the light reflectivity is at least 75%, the incident light having passed through the cell and having gone inside could be effectively brought back to the cell, and the power generation efficiency-improving effect could be large. When the white pigment content is controlled, for example, within a range of from 2.5 to 30 g/m², then the light reflectivity could be controlled to be at least 75%.

If desired, a crosslinking agent, a surfactant, a filler and others may be added to the white layer.

Crosslinking Agent

In the invention, it is desirable that the white layer contains a structural part derived from a crosslinking agent that crosslinks polymers.

The crosslinking agent includes epoxy-type, isocyanate-type, melamine-type, carbodiimide-type, oxazoline-type crosslinking agents, etc. Crosslinked with such a crosslinking agent, the adhesiveness after wet heat aging, concretely, the adhesiveness of the layer to the adjacent material such as a sealant or the like when exposed to wet heat environments could be improved more.

The crosslinking agent includes epoxy-type, isocyanate-type, melamine-type, carbodiimide-type, oxazoline-type crosslinking agents, etc. Of those crosslinking agents, preferred are carbodiimide-type compounds, oxazoline-type compounds and the like crosslinking agents.

Specific examples of the oxazoline-type crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis(2-oxazoline), 2,2′-m-phenylene-bis-(4,4′-dimethyl-2-oxazoline), bis-(2-oxazolinylcyclohexane)sulfide, bis-(2-oxazolinylnorbornane)sulfide, etc. Further, (co)polymers of those compounds are preferably used here.

As oxazoline group-having compounds, also usable here are Epocross K2010E, K2020E, K2030E, WS-500, WS-700 (all by Nippon Shokubai), etc.

Specific examples of the carbodiimide-type crosslinking agent include dicyclohexylmethane carbodiimide, tetramethylxylylene carbodiimide, dicyclohexylmethane carbodiimide, etc. Also preferred for use herein are the carbodiimide compounds described in JP-A 2009-235278. Concretely, as the carbodiimide-type crosslinking agent, usable here are commercial products of Carbodilite SV-02, Carbodilite V-02, Carbodilite V-02-L2, Carbodilite V-04, CarbodiliteE-01, CarbodiliteE-02 (all by Nisshinbo Chemical), etc.

The amount of the crosslinking agent is preferably from 5 to 50% by mass relative to the binder in the layer, more preferably from 10 to 40% by mass. When the amount of the crosslinking agent is at least 5% by mass, then a sufficient crosslinking effect could be obtained while the strength and the adhesiveness of the color layer could be kept well; and when at most 50% by mass, the pot life of the coating liquid could be kept long.

Surfactant

As the surfactant, herein usable are any known surfactants such as anionic and nonionic surfactants and others. When such a surfactant is added, its amount is preferably from 0.1 to 15 mg/m², more preferably from 0.5 to 5 mg/m². When the amount of the surfactant added is at least 0.1 mg/m², then a good layer could be formed while preventing cissing; and when at most 15 mg/m², the layer could have good adhesiveness.

Method for Forming White Layer

The white layer may be formed according to a method of sticking a pigment-containing polymer sheet, a method of co-extrusion of a color layer in substrate formation, a method of coating, etc. Concretely, the white layer may be formed on the surface of the polyester support via an undercoat layer therebetween to be mentioned below, by sticking, coextrusion, coating or the like.

Of the above, the coating method is preferred since it is simple and enables formation of a uniform and thin film.

In case where the layer is formed by coating, employable here as the coating method is any known coating method with a gravure coater, a bar coater, etc.

The coating liquid may be a water-based liquid using water as a coating medium, or may be a solvent-based liquid using an organic solvent such as toluene, methyl ethyl ketone, etc. Above all, preferred is use of water as the solvent from the viewpoint of environmental load reduction. One alone or two or more different types of coating solvents may be used here either singly or as combined. Preferred is a coating method where a water-based coating liquid is prepared by dispersing a binder in water and used for coating. In this case, the proportion of water in the solvent is preferably at least 60% by mass, more preferably at least 80% by mass.

More preferably, the white layer is formed by coating. For example, the fact that the white layer was formed by coating may be confirmed by the quantification analysis to confirm that the residual solvent amount relative to the entire amount of the polymer layer in the solar cell protective sheet is at most 1000 ppm. More preferably, the residual solvent amount relative to the entire amount of the polymer layer in the solar cell protective sheet is at most 500 ppm, even more preferably at most 100 ppm.

Polymer Layer as Back Layer

In case where the polymer layer is a back layer in the invention, it is desirable that the layer contains at least one of a fluoropolymer and a silicone-acrylic composite resin, and optionally the layer may contain any other components such as various types of additives. In the solar cell protective sheet of the invention, it is desirable that the weather-resistant layer is a coating layer formed by coating with a water-based composition for weather-resistant layer that contains at least one of a fluoropolymer and a silicone-acrylic composite resin.

In a solar cell having a laminate configuration of battery-side substrate [=transparent substrate on the side on which sunlight falls (glass substrate, etc.)/solar cell element-containing element constitutive part]/solar cell back sheet, the back layer is a back-protective layer that is arranged on the side opposite to the battery-side substrate of the polyester support, and may have a monolayer structure or a laminate structure of two or more layers. Containing a polymer, the adhesiveness of the layer to the polyester support is good; and when the back layer comprises two or more layers and when one layer thereof is the polymer layer in the invention, the interlayer adhesiveness between the layers is good. In addition, the layer secures degradation resistance in wet heat environments. Accordingly, in one preferred embodiment of the invention, the polymer layer may be arranged as the outermost layer serving as a back layer, which is positioned on the back side relative to the solar cell element in a module.

### (Weather-Resistant Layer Containing Silicone-Acrylic Composite Resin)

The constitutive components to constitute the weather-resistant layer that contains a silicone-acrylic composite resin are described in detail hereinunder.

Silicone-Acrylic Composite Resin

Preferably, the solar cell protective sheet of the invention has, as the polymer layer therein, a weather-resistant layer that contains a silicone-acrylic composite resin.

The weather-resistant layer contains a silicone-acrylic composite resin that is a type of a silicone polymer. The silicone polymer is meant to indicate one that contains at least one polymer having a (poly)siloxane structure in the molecular chain thereof. Containing such a silicone polymer, the layer is more excellent in the adhesiveness to the adjacent material of the polyester support or the fluoropolymer serving as a weather-resistant layer and in the durability under in wet heat environments.

Having a (poly)siloxane structure in the molecular chain thereof, the silicone polymer is not specifically defined. Preferred area homopolymer (monopolymer) of a compound having a (poly)siloxane structural unit, and a copolymer of such a (poly)siloxane structural unit-having compound and any other compound, or that is, a copolymer having a (poly)siloxane structural unit and any other structural unit. The other compound is a non-siloxane monomer or polymer, and the other structural unit is a non-siloxane structural unit.

Preferably, the silicone polymer has, as the (poly)siloxane structure therein, a (poly)siloxane structural unit represented by the following general formula (1):

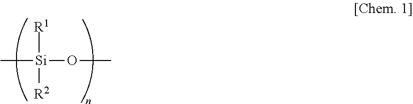

In the above-mentioned general formula (1), R¹ and R² each independently represent a hydrogen atom, a halogen atom, or a monovalent organic group. Here, R¹ and R² may be the same or different, and multiple R¹'s and R²'s each may be the same or different. n indicates an integer of 1 or more.

In the moiety of the (poly)siloxane segment, “—(Si(R¹)(R²)—O)ₙ—” (the (poly)siloxane structural unit represented by the general formula (1)) in the silicone polymer, R¹ and R² may be the same or different, each representing a hydrogen atom, a halogen atom, or a monovalent organic group.

“—(Si(R¹)(R²)—O)ₙ—” is a (poly)siloxane segment derived from various (poly)siloxanes having a linear, branched or cyclic structure.

The halogen atom to be represented by R¹ and R² includes a fluorine atom, a chlorine atom, an iodine atom, etc.

“Monovalent organic group” to be represented by R¹ and R² is a group capable of covalent-bonding to the Si atom, and may be unsubstituted or may have a substituent. The monovalent organic group includes, for example, an alkyl group (e.g., methyl group, ethyl group, etc.), an aryl group (e.g., phenyl group, etc.), an aralkyl group (e.g., benzyl group, phenylethyl group, etc.), an alkoxy group (e.g., methoxy group, ethoxy group, propoxy group, etc.), an aryloxy group (e.g., phenoxy group, etc.), a mercapto group, an amino group (e.g., amino group, diethylamino group, etc.), an amide group, etc.

Above all, from the viewpoint of the adhesiveness of the polymer layer to the adjacent material such as the polyester support and the weather-resistant layer formed of a fluoropolymer or the like and of the durability thereof in wet heat environments, it is desirable that R¹ and R² each are independently a hydrogen atom, a chlorine atom, a bromine atom, an unsubstituted or substituted alkyl group having from 1 to 4 carbon atoms (especially a methyl group, an ethyl group)m an unsubstituted or substituted phenyl group, an unsubstituted or substituted alkoxy group, a mercapto group, an unsubstituted amino group, or an amide group; and from the viewpoint of the durability in wet heat environments, more preferred is an unsubstituted or substituted alkoxy group (preferably an alkoxy group having from 1 to 4 carbon atoms).

n is preferably from 1 to 5000, more preferably from 1 to 1000.

The proportion of the moiety “—(Si(R¹)(R²)—O)ₙ—” (the (poly)siloxane structural unit represented by the general formula (1)) in the silicone polymer is preferably from 15 to 85% by mass relative to the total mass of the silicone polymer. Above all, from the viewpoint that the polymer of the type is more excellent in the adhesiveness thereof to the adjacent material such as the polyester support and the weather-resistant layer formed of a fluoropolymer or the like and in the durability thereof in wet heat environments, the proportion is more preferably from 20 to 80% by mass. When the proportion of the (poly)siloxane structural unit is at least 15% by mass, then the strength of the surface of the polymer layer is high and therefore the layer could be prevented from having flaws owing to scratching, abrasion or collision with flying small stones, etc., and in addition, the polymer layer could be excellent in the adhesiveness to the adjacent materials of the polyester support, etc. Since the polymer layer is prevented from having flaws, the weather resistance thereof may be thereby enhanced, and the peeling resistance that may often worsen when given heat or moisture, as well as the shape stability and the adhesiveness durability in exposure to wet heat environments can be effectively enhanced. When the proportion of the (poly)siloxane structural unit is at most 85% by weight, then the liquid could be kept stable.

The silicone-acrylic composite resin in the invention is a copolymer having a (poly)siloxane structural unit and at least an acrylic structural unit. Preferably, the resin contains, in the molecular chain thereof, a (poly)siloxane structural unit represented by the above-mentioned general formula (1) in an amount of from 15 to 85% by mass and a non-siloxane structural unit containing an acrylic structural unit in an amount of from 85 to 15% by mass. Containing the copolymerization polymer of the type, the film strength of the polymer layer is high and therefore flaws through scratching or abrasion could be prevented from forming on the surface of the layer, and the adhesiveness of the polymer layer to the polyester support and the weather-resistant layer formed of a fluoropolymer, or that is, the durability thereof including peeling resistance peeling resistance that may often worsen when given heat or moisture, as well as shape stability and durability in exposure to wet heat environments can be more dramatically enhanced than before.

The copolymerization polymer is preferably a block copolymer produced through copolymerization of a siloxane compound (including polysiloxane) and a compound selected from a non-siloxane monomer or a non-siloxane polymer and having a (poly)siloxane structural unit represented by the above-mentioned general formula (1) and a non-siloxane structural unit. In this case, one alone or two more different types of siloxane compounds and non-siloxane monomers or non-siloxane polymers to be polymerized may be used here either singly or as combined.

The non-siloxane structural unit (derived from a non-siloxane monomer or a non-siloxane polymer) to copolymerize with the (poly)siloxane structural unit is not specifically defined except that it contains at least an acrylic structural unit, and may be a polymer segment derived from any polymer. The polymer (prepolymer) that is a precursor of the polymer segment includes, for example, various types of polymers such as vinyl polymers, polyester polymers, polyurethane polymers, etc.

Above all, preferred are vinyl polymers and polyurethane polymers from the viewpoint that they are easy to prepare and they are excellent in hydrolysis resistance; and more preferred are vinyl polymers.

Typical examples of the vinyl polymers include various polymers of acrylic polymers, vinyl carboxylate polymers, aromatic vinyl polymers, fluoro-olefin polymers, etc. Above all, acrylic polymers are especially preferred from the viewpoint of the planning latitude thereof. In particular, it is desirable that, in the solar cell protective sheet of the invention, the silicone-acrylic composite resin to constitute the weather-resistant layer is a composite polymer of a silicone resin and an acrylic resin.

One alone or two or more different types of polymers to constitute the non-siloxane structural unit may be used here either singly or as combined.

The binder in the weather-resistant layer that contains the silicone-acrylic composite resin is preferably a composite polymer in which the polysiloxane segment comprises any of a hydrolyzed condensate of dimethyldimethoxysilane/γ-methacryloxytrimethoxysilane or a hydrolyzed condensate of dimethyldimethoxysilane/diphenyldimethoxysilane/γ-methacryl oxytrimethoxysilane and in which the polymer structure moiety to copolymerize with the polysiloxane segment is an acrylic polymer that comprises a monomer component selected from ethyl acrylate, butyl acrylate, hydroxyethyl acrylate, 2-ethylhexyl acrylate methyl methacrylate, methyl methacrylate, butyl methacrylate, hydroxyethyl acrylate, acrylic acid and methacrylic acid; and more preferred is a composite polymer that comprises a hydrolyzed condensate of dimethyldimethoxysilane/γ-methacryloxytrimethoxysilane as the polysiloxane segment thereof and comprises an acrylic polymer comprising a monomer component selected from methyl methacrylate, ethyl acrylate, acrylic acid and methacrylic acid.

Preferably, the prepolymer to constitute the non-siloxane structural unit is one containing at least one of an acid group and a neutralized acid group and/or a hydrolyzable silyl group. Of those prepolymers, a vinyl polymer may be prepared according to various methods, for example, according to (a) a method of copolymerizing an acid group-containing vinyl monomer and a vinyl monomer containing a hydrolyzable silyl group and/or a silanol group, along with a monomer copolymerizable with these, (2) a method of reacting a previously-prepared vinyl polymer that contains a hydroxyl group as well as a hydrolyzable silyl group and/or a silanol group, with a polycarboxylic acid anhydride, or (3) a method of reacting a previously-prepared vinyl polymer that contains an acid anhydride group as well as a hydrolyzable silyl group and/or a silanol group, with a compound having active hydrogen (water, alcohol, amine, etc.).

The prepolymer may be produced and may be obtained, for example, according to the method described in the paragraphs [0021] to [0078] in JP-A 2009-52011.

The weather-resistant layer containing the silicone-acrylic composite resin in the invention may use, as the binder therein, the silicone-acrylic composite resin either singly or as combined with any other polymer. In case where the binder comprises the other polymer, it is desirable that the content ratio of the (poly)siloxane structure-containing silicone-acrylic composite resin in the layer is at least 30% by mass of the entire binder amount, more preferably at least 60% by mass. When the content ratio of the silicone-acrylic composite resin is at least 30% by mass, then the adhesiveness of the layer to the polyester support and to the fluoropolymer-containing weather resistant layer and also the durability thereof in wet heat environments could be more excellent.

Preferably, the molecular weight of the silicone-acrylic composite resin is from 5,000 to 100,000, more preferably from 10,000 to 50,000.

For preparing the silicone-acrylic composite resin, usable here are various methods of (i) a method of reacting the prepolymer with a polysiloxane having a structural unit represented by the above-mentioned general formula (1), (ii) a method of hydrolyzing and condensing a silane compound having a structural unit represented by the above-mentioned general formula (1) in which R¹ and/or R² each are a hydrolyzable group, in the presence of the prepolymer, etc.

Various types of silane compounds may be used in the method (ii), but especially preferred are alkoxysilane compounds.

In case where the silicone-acrylic composite resin is prepared according to the method (i), for example, water and a catalyst are optionally added to a mixture of the prepolymer and the polysiloxane, and the mixture is reacted at a temperature of from 20 to 150° C. or so for from 30 minutes to 30 hours or so (preferably at 50 to 130° C. and for 1 to 20 hours). As the catalyst, usable are various types of silanol condensation catalysts such as acid compounds, basic compounds, metal-containing compounds, etc.

In case where the silicone-acrylic composite resin is prepared according to the method (ii), for example, water and a silanol condensation catalyst are added to a mixture of the prepolymer and the alkoxysilane compound, and the mixture is reacted for hydrolytic condensation at a temperature of from 20 to 150° C. or so for from 30 minutes to 30 hours or so (preferably at 50 to 130° C. and for 1 to 20 hours).

As the (poly)siloxane structure-having silicone-acrylic composite resin, usable here are commercially-available products, and for example, usable are DIC's Ceranate series (for example, Ceranate WSA1070, WSA1060, etc.), Asahi Kasei Chemicals' H7600 series (H7650, H7630, H7620, etc.), JSR's inorganic/acrylic composite emulsions, etc.

The content ratio of the (poly)siloxane structure-having silicone-acrylic composite resin in one weather-resistant layer is preferably within a range of from more than 0.2 g/m² to 15 g/m². When the polymer content ratio is at least 0.2 g/m², then the content of the silicone-acrylic composite resin could be enough to enhance the scratch resistance of the polymer layer. When the content ratio is at most 15 g/m², then the amount of the silicone-acrylic composite resin is not too much and therefore the weather-resistant layer could be well cured.

Within the above range, the content is more preferably from 0.5 g/m² to 10.0 g/m², even more preferably from 1.0 g/m² to 5.0 g/m² from the viewpoint of the surface strength of the weather-resistant layer.

White Pigment

Preferably, the weather-resistant layer that contains the silicone-acrylic composite resin further contains, in addition to the silicone-acrylic composite resin therein, a white pigment from the viewpoint of the light-reflecting function of the layer and of the improvement of the lightfastness of the layer.

As the white pigment, preferred is an inorganic pigment such as titanium dioxide, barium sulfate, silicon oxide, aluminium oxide, magnesium oxide, calcium carbonate, kaolin, talc, colloidal silica, etc., or an organic pigment such as hollow particles, etc.

The function of the white pigment-containing layer is, first, to reflect the moiety of the incident light having passed through the solar cell and having reached the back sheet not used for power generation, to bring back it to the solar cell thereby increasing the power generation efficiency of a solar cell module, and secondly, to improve the decorativeness of the outward appearance of a solar cell module when seen from the side thereof on which sunlight falls (front side), etc. In general, when a solar cell module is seen from the front side thereof, then the back sheet is seen in the periphery of the solar cell, and by providing a white pigment-containing layer in the back sheet, the decorativeness of the resulting module can be improved and the module could thereby get good-looking.

Further adding a white pigment to the silicone-acrylic composite resin-containing weather-resistant layer in addition to the silicone polymer thereto increases the reflectivity of the polymer sheet and reduces yellowing of the sheet in a long-term high-temperature high-humidity test (for 2000 to 3000 hours at 85° C. and a relative humidity of 85%) and in a UV irradiation test (to a total dose of 45 Kwh/m² according to the UV test of IEC 61215. Further, adding a white pigment to the silicone-acrylic composite resin-containing weather-resistant layer improves more the adhesiveness of the layer to other layers.

Preferably, in the polymer sheet of the invention, the content of the white pigment to be contained in the silicone-acrylic composite resin-containing weather-resistant layer is from 1.0 g/m² to 15 g/m² per one polymer layer. When the content of the white pigment is at least 1.0 g/m², then the layer could effectively provide good reflectivity and UV resistance (lightfastness). On the other hand, when the content of the white pigment in the silicone-acrylic composite resin-containing weather-resistant layer is at most 15 g/m², then the surface condition of the color layer could be kept good with ease and the film strength thereof could be excellent. Above all, it is more desirable that the content of the white pigment in the silicone-acrylic composite resin-containing weather-resistant layer falls within a range of from 2.5 to 10 g/m² per one polymer layer, even more preferably from 4.5 to 8.5 g/m².

Preferably, the mean particle size of the white pigment is from 0.03 to 0.8 μm as the volume-average particle size thereof, more preferably from 0.15 to 0.5 μm or so. When the mean particle size falls within the range, then the light reflectivity of the layer could be high. The mean particle size is a value measured with a laser analyzing/scattering particle sizer LA950 (by Horiba Seisakusho).

The content of the binder component (including the above-mentioned silicone polymer) in the silicone-acrylic composite resin-containing weather-resistant layer is preferably within a range of from 15 to 200% by mass relative to the white pigment therein, more preferably within a range of from 17 to 100% by mass. When the binder content is at least 15% by mass, then the strength of the color layer could be sufficient; and when at most 200% by mass, then the reflectivity and the decorativeness of the layer could be kept well.

Other Components in Silicone-Acrylic Composite Resin-Containing Weather-Resistant Layer

The other components capable of being contained in the silicone-acrylic composite resin-containing weather-resistant layer include a crosslinking agent, a surfactant, a filler, etc.

In the polymer sheet of the invention, preferably, at least one of the second polymer layer and the silicone-acrylic composite resin-containing weather-resistant layer contains a crosslinking agent in an amount of from 0.5 to 30% by mass relative to the entire binder in the polymer layer. By adding a crosslinking agent to the binder (binder resin) that constitutes mainly the silicone-acrylic composite resin-containing weather-resistant layer to form the silicone-acrylic composite resin-containing weather-resistant layer, the formed layer could have a crosslinked structure derived from the crosslinking agent.

The crosslinking agent includes epoxy-type, isocyanate-type, melamine-type, carbodiimide-type, oxazoline-type crosslinking agents, etc. Of those, it is desirable that, in the polymer sheet of the invention, the crosslinking agent in the second polymer is at least one crosslinking agent selected from a carbodiimide-type crosslinking agent, an oxazoline-type crosslinking agent and an isocyanate-type crosslinking agent. The description and the preferred ranges of the carbodiimide-type and oxazoline-type crosslinking agents are the same as the description and the preferred ranges of the crosslinking agents for use in the first polymer layer mentioned hereinabove; and the description and the preferred range of the isocyanate-type crosslinking agent are the same as the description and the preferred range of the isocyanate-type crosslinking agent for use in the second polymer layer mentioned hereinabove.

The amount of the crosslinking agent to be added is preferably from 0.5 to 30% by mass relative to the binder to that constitutes the silicone-acrylic composite resin-containing weather-resistant layer, more preferably from 3% by mass to less than 15% by mass. When the amount of the crosslinking agent added is at least 0.5% by mass, then the agent could provide a sufficient crosslinking effect while the strength and the adhesiveness of the silicone-acrylic composite resin-containing weather-resistant layer are kept high; and when at most 30% by mass, the pot life of the coating liquid could be kept long, and when less than 15% by mass, the surface condition of the coating layer could be improved.

As the surfactant, usable are any known surfactants such as anionic and nonionic surfactants and others. When such a surfactant is added, its amount is preferably from 0.1 to 10 mg/m², more preferably from 0.5 to 3 mg/m². When the amount of the surfactant added is at least 0.1 mg/m², then a good layer could be formed while preventing cissing; and when at most 10 mg/m², the adhesiveness of the layer to the polyester support and to the fluoropolymer layer could be kept good.

A filler may be further added to the silicone-acrylic composite resin-containing weather resistant layer. As the filler, usable are any known fillers such as colloidal silica, titanium dioxide, etc.

The amount of the filler to be added is preferably at most 20% by mass relative to the binder in the silicone-acrylic composite resin-containing weather-resistant layer, more preferably at most 15% by mass. When the amount of the filler added is at most 20% by mass, then the surface condition of the silicone-acrylic composite resin-containing weather-resistant layer could be kept better.

Preferably, the thickness of one layer of the silicone-acrylic composite resin-containing weather-resistant layer is generally from 0.3 μm to 22 μm, more preferably from 0.5 μm to 15 μm, even more preferably from 0.8 μm to 15 μm, still more preferably from 1.0 μm to 15 μm, further more preferably from 2 to 15 μm, and most preferably from 5 to 15 μm. When the thickness of the polymer layer is at least 0.3 μm and further at least 0.8 μm, then moisture could hardly penetrate through the surface of the polymer layer to run inside the layer when exposed to wet heat environments, or that is, moisture could hardly reach the interface between the silicone-acrylic composite resin-containing weather-resistant layer and the polyester support and the adhesiveness of the polymer layer could be thereby markedly improved. On the other hand, when the thickness of the silicone-acrylic composite resin-containing weather-resistant layer is at most 22 μm and further at most 15 μm, then the polymer layer itself could be prevented from being brittle and, when exposed to wet heat environments, the polymer layer could be prevented from being broken and the adhesiveness thereof could be thereby improved.

The silicone-acrylic composite resin-containing weather-resistant layer may be formed by applying a coating liquid that contains a binder and others, onto the polyester support and by drying it thereon. After dried, the layer may be cured by heating. The coating method and the solvent for the coating liquid to be used are not specifically defined.

In the coating method, for example, a gravure coater or a bar coater may be used.

The solvent for use in the coating liquid may be water, or may also be an organic solvent such as toluene, methyl ethyl ketone, etc. One alone or two or more different types of solvents may be used either singly or as combined. Preferably, a binder is dispersed in water to prepare a water-based coating liquid, and this is applied onto the support. In this case, the proportion of water in the solvent is preferably at least 60% by mass, more preferably at least 80% by mass.

In case where the polyester support is a biaxially-stretched film, the coating liquid that is to form the silicone-acrylic composite resin-containing weather-resistant layer may be applied onto the biaxially-stretched polyester support and then the coating film may be dried; or the coating liquid may be applied onto the polyester support after monoaxially stretched, then dried, and thereafter the thus-coated support may be stretched in the direction different from the original stretching direction. Further, the coating liquid may be applied onto the polyester support not as yet stretched, then dried, and the thus-coated support may be stretched in two directions.

Arrangement of Weather-Resistant Layer

In the solar cell protective sheet of the invention, the polymer layer contains a silicone-acrylic composite resin, and is therefore excellent in adhesiveness to the adjacent material of the polyester support and others and is additionally excellent in adhesiveness durability when exposed to wet heat environments. Preferably, in the solar cell protective sheet of the invention, the weather-resistant layer is arranged in contact with the polyester support therein.

One polymer layer may be arranged as the weather-resistant layer, or as the case may be, multiple polymer layers may be arranged as laminated.

In one preferred embodiment where one polymer layer is arranged as the weather-resistant layer, the silicone-acrylic composite resin-containing layer may be arranged in contact with the polyester support.

On the other hand, for laminating multiple polymer layers to form the weather-resistant layer, preferred are an embodiment where two layers each containing the silicone-acrylic composite resin are laminated on the polyester support, and an embodiment where the silicone-acrylic composite resin-containing weather-resistant layer is formed in contact with the polyester support and a fluoropolymer-containing weather-resistant layer is further laminated thereon. Above all, more preferred is the embodiment where the silicone-acrylic composite resin-containing weather-resistant layer is formed in contact with the polyester support and a fluoropolymer-containing weather-resistant layer is further laminated thereon.

### (Fluoropolymer-Containing Weather-Resistant Layer)

Preferably, the polymer sheet of the invention has a fluoropolymer-containing weather-resistant layer that is arranged on the silicone-acrylic composite resin-containing weather-resistant layer.

Preferably, the fluoropolymer-containing weather-resistant layer is formed directly on the fluoropolymer-containing weather-resistant layer. The fluorine-containing polymer that is the fluoropolymer-containing weather-resistant layer comprises a fluoropolymer (fluorine-containing polymer) as the main binder. The main binder is the binder of which the content is the largest in the fluorine-containing polymer layer. The fluoropolymer-containing weather-resistant layer is concretely described hereinunder.

Fluoropolymer

Not specifically defined, the fluoropolymer for use in the fluoropolymer-containing weather-resistant layer may be any and every polymer having a recurring unit represented by —(CFX¹—CX²X³)—. (In this, X¹, X² and X³ each represent a hydrogen atom, a fluorine atom, a chlorine atom, or a perfluoroalkyl group having from 1 to 3 carbon atoms.) Concrete examples of the polymer include polytetrafluoroethylene (hereinafter this may be referred to as PTFE), polyvinyl fluoride (hereinafter this may be referred to as PVF), polyvinylidene fluoride (hereinafter this may be referred to as PVDF), polytrifluoroethylene chloride (hereinafter this may be referred to as PCTFE), polytetrafluoropropylene (hereinafter this may be referred to as HFP), etc.

These polymers may be homopolymers prepared through polymerization of a single monomer or copolymers of two or more different types of monomers. Examples of the copolymers include a copolymer formed through copolymerization of tetrafluoroethylene and tetrafluoropropylene (abbreviated as P(TFE/HFP)), a copolymer formed through copolymerization of tetrafluoroethylene and vinylidene fluoride (abbreviated as P(TFE/VDF)).

Further, as the polymer for use in the fluoropolymer-containing weather-resistant layer, also usable is a copolymer of a fluoromonomer represented by —(CFX¹—CX²X³)— and any other monomer. Examples of the copolymer include a copolymer of tetrafluoroethylene and ethylene (abbreviated as P(TFE/E)), a copolymer of tetrafluoroethylene and propylene (abbreviated as P(TFE)P), a copolymer of tetrafluoroethylene and vinyl ether (abbreviated as P(TFE/VE)), a copolymer of tetrafluoroethylene and perfluorovinyl ether (abbreviated as P(TFE/FVE)), a copolymer of chlorotrifluoroethylene and vinyl ether (abbreviated as P(CTFE/VE)), a copolymer of chlorotrifluoroethylene and perfluorovinyl ether (abbreviated as P(CTFE/FVE)), etc.

The fluoropolymer may be dissolved in an organic solvent or, or fine particles thereof may be dispersed in water. From the viewpoint of low environmental load, the latter is preferred. Aqueous dispersion of fluoropolymer are described, for example, in JP-A 2003-231722, 2002-20409, 9-194538.

Concretely, preferred are trifluoroethylene chloride/perfluoroethyl vinyl ether copolymer, trifluoroethylene chloride/perfluoroethyl vinyl ether/methacrylic acid copolymer, trifluoroethylene chloride/ethyl vinyl ether copolymer, trifluoroethylene chloride/ethyl vinyl ether/methacrylic acid copolymer, vinylidene fluoride/methyl methacrylate/methacrylic acid copolymer, vinyl fluoride/ethyl acrylate/acrylic acid copolymer; and more preferred are trifluoroethylene chloride/perfluoroethyl vinyl ether/methacrylic acid copolymer, trifluoroethylene chloride/ethyl vinyl ether copolymer.

As the binder in the fluoropolymer-containing weather-resistant layer, one or more of the above-mentioned fluoropolymers may be used either singly or as combined. If desired, any other resin than the fluoropolymer, such as an acrylic resin, a polyester resin, a polyurethane resin, a polyolefin resin, a silicone resin or the like may be used together with the fluoropolymer, within a range not overstepping 50% by mass of the total binder. However, when the amount of the other resin than the fluoropolymer is more than 50% by mass and when the layer is used in a back sheet, then the weather resistance of the sheet may be poor.

Organic Lubricant

Preferably, the fluoropolymer-containing weather-resistant layer contains at least one organic lubricant. Containing an organic lubricant, the layer is free from the risk of lubricity reduction owing to the fluoropolymer therein (or that is, the layer is free from increase in the kinetic friction coefficient thereof), and as a result, the risk of the layer that would readily be flawed owing to the external force applied thereto, such as scratching, abrasion, collision with small stones or the like could be greatly relaxed. In addition, the lubricant can prevent the coating liquid from undergoing on-plane cissing, which, however, would often occur in use of a fluoropolymer, and as a result, a fluoropolymer-containing weather-resistant layer having a good surface condition can be formed.

Preferably, the organic lubricant is contained in the fluoropolymer-containing weather-resistant layer in an amount falling within a range of from 0.2 to 500 mg/m². When the content ratio of the organic lubricant is at least 0.2 mg/m², then the scratching resistance of the layer could be sufficiently improved owing to the effect of the organic lubricant to lower the kinetic friction coefficient. On the other hand, when the content ratio of the organic lubricant is at most 500 mg/m², then coating unevenness and aggregation would hardly occur in forming the fluoropolymer-containing weather-resistant layer by coating, and cissing failure would also hardly occur.

Within the above-mentioned range, more preferred is a range of from 1 mg/m² to 300 mg/m², even more preferred is a range of from 5 mg/m² to 200 mg/m², and still more preferred is a range of from 10 mg/m² to 150 mg/m², from the viewpoint of the kinetic friction coefficient-reducing effect and the coatability.

The organic lubricant includes, for example, synthetic was compounds, natural wax compounds, surfactant compounds, inorganic compounds, organic resin compounds, etc. Above all, from the viewpoint of the surface strength of the fluoropolymer-containing weather-resistant layer, it is desirable that the organic lubricant contained in the fluoropolymer-containing weather-resistant layer is at least one selected from polyolefin compounds, synthetic wax compounds, natural wax compounds and surfactant compounds.

The polyolefin compounds include, for example, olefin waxes such as polyethylene wax, polypropylene wax, etc.

The synthetic was compounds include, for example, synthetic hydrocarbon waxes (except olefin waxes), such as esters of stearic acid, oleic acid, erucic acid, lauric acid, behenic acid, palmitic acid, adipic acid or the like, amides, bisamides, ketones, metal salts and their derivatives, Fischer-Tropsch wax, etc.; hydrogenated waxes of phosphates, hardened castor oil, hardened castor oil derivatives, etc.

The natural wax compounds include, for example, vegetable waxes such as carnauba wax, candelilla wax, Japan wax, etc.; petroleum waxes such as paraffin wax, microcrystalline wax, etc.; mineral waxes such as montan wax, etc.; animal waxes such as bees wax, lanolin, etc.

The surfactant compounds include, for example, cationic surfactants such as alkylamine salts, etc.; anionic surfactants such as alkyl sulfate ester salts, etc.; nonionic surfactants such as polyoxyethylene alkyl ether, etc.; ampholytic surfactants such as alkylbetaine, etc.; fluorosurfactants, etc.

As the organic lubricant, commercially-available products may be used here. Concretely, as organic lubricants of polyolefin compounds, for example, there are mentioned Mitsui Chemical's Chemipearl series (for example, Chemipearl W700, W900, W950, etc.), Chukyo Yushi's Polylon P-502, etc.;

as organic lubricants of synthetic waxes, for example, there are mentioned Chukyo Yushi's Himicron L-271, Hidrin L-536, etc.;

as organic lubricants of natural waxes, for example, there are mentioned Chukyo Yushi's Hidrin L-703-35, Selosol 524, Selosol R-586, etc.; and

as organic lubricants of surfactants, for example, there are mentioned Nikko Chemicals' NIKKO series (for example, NIKKOL SCS, etc.), Kao's Emal series (for example, Emal 40, etc.).

Among the above, preferred is adding a polyethylene wax compound as the organic lubricant from the viewpoint of scratch resistance and surface improvement; and above all, more preferred is use of Mitsui Chemical's Chemipearl series from the viewpoint that the lubricity can be greatly improved and the scratch resistance and the surface appearance can also be improved.

Other Additives

If desired, colloidal silica, silane coupling agent, crosslinking agent, surfactant and the like may be added to the fluoropolymer-containing weather-resistant layer.

Colloidal silica may be added to the fluoropolymer-containing weather-resistant layer for improving the surface condition of the layer.

Colloidal silica for use in the invention is such that fine particles comprising silicon oxide as the main ingredient thereof exist as a colloidal aggregate in a dispersing medium of water, or a monoalcohol or diol, or a mixture thereof.

The particle size of the colloidal silica particles may be from a few nm to 100 nm or so as the mean primary particle size thereof.

The mean particle size may be measured on an electromicroscopic image taken with a scanning electronic microscope (SEM) or the like, or may be measured with a particle sizer or the like using a dynamic light-scattering method or a static light-scattering method.

The shape of the colloidal silica particles may be spherical or such spherical particles may bond to each other in long strands.

Colloidal silica particles are available on the market, and for example, there are mentioned Nissan Chemical's Snowtex series, JGC Catalysts and Chemicals' Cataloid-S series, Bayer's Levasil series, etc.

Concretely, for example, there are mentioned Nissan Chemical's Snowtex ST-20, ST-30, ST-40, ST-C, ST-N, ST-20L, ST-O, ST-OL, ST-S, ST-XS, ST-XL, ST-YL, ST-ZL, ST-OZL, ST-AK, Snowtex-AK series, Snowtex-PS series, Snowtex-UP series, etc.

Of those colloidal silicas, preferred for use in the invention are bead-like bonded long strands, such as Snowtex-UP series.

The amount of the colloidal silica to be added is preferably from 0.3 to 1.0% by mass, more preferably from 0.5 to 0.8% by mass. When the amount thereof is at least 0.3% by mass, the colloidal silica added could provide a surface condition-improving effect; and when at most 1.0% by mass, the coating liquid could be prevented from aggregating.

In case where such colloidal silica is added to the fluoropolymer-containing weather-resistant layer, it is desirable that a silane coupling agent is also added thereto from the viewpoint of surface improvement. As the silane coupling agent, preferred is an alkoxysilane compound, and for example, there are mentioned tetraalkoxysilanes, trialkoxysilanes, etc. Above all, preferred are trialkoxysilanes, and especially preferred are alkoxysilane compounds having an amino group. In case where a silane coupling agent is added to the layer, the amount thereof is preferably from 0.3 to 1.0% by mass relative to the fluoropolymer-containing weather-resistant layer, more preferably from 0.5 to 0.8% by mass. When the amount is at least 0.3% by mass, then the layer could enjoy the surface-improving effect; and when at most 1.0% by mass, then the coating liquid could be prevented from aggregating.

When a crosslinking agent is added to the fluoropolymer-containing weather-resistant layer to form a fluoropolymer layer, then a crosslinked structure-derived form the crosslinking agent could be formed in the layer.

The crosslinking agent for use in the fluoropolymer-containing weather-resistant layer includes epoxy-type, isocyanate-type, melamine-type, carbodiimide-type and oxazoline-type crosslinking agents, etc. Examples of the carbodiimide-type crosslinking agent include, for example, Carbodilite V-02-L2 (by Nisshinbo); and examples of the oxazoline-type crosslinking agent include, for example, Epocross WS-700 and Epocross K-2020E (both by Nippon Shokubai).

As the surfactant for use in the fluoropolymer-containing weather-resistant layer, any known surfactants such as anionic or nonionic surfactants and the like are usable here. The amount of the surfactant, when added to the layer, is preferably from 0 to 15 mg/m², more preferably from 0.5 to 5 mg/m². When the amount of the surfactant is at least 0.1 mg/m², then a good layer could be formed while preventing cis sing; and when at most 15 mg/m², the adhesiveness of the layer could be bettered.

Preferably, the thickness of the fluoropolymer-containing weather-resistant layer is within a range of from 0.8 to 12 μm. When the thickness of the fluoropolymer layer is at least 0.8 μm, then the durability (weather resistance) of the polymer sheet for solar cell back sheets, especially as the outermost layer thereof could be sufficient; and when at most 12 μm, then the surface condition of the layer would hardly worsen and the adhesion power thereof to the silicone-acrylic composite resin-containing weather-resistant layer would be sufficient. When the thickness of the fluoropolymer-containing weather-resistant layer falls within a range of from 0.8 to 12 μm, then both the durability and the surface condition could be bettered, and in particular, the thickness is more preferably within a range of from 1.0 to 10 μm or so, even more preferably within a range of from 2.0 to 8.0 μm.

In the polymer sheet of the invention, any additional layer may be further laminated on the fluoropolymer-containing layer that is the fluoropolymer-containing weather resistant layer. However, from the viewpoint of improving the durability of the polymer sheet and from the viewpoint of weight reduction, thickness reduction and cost reduction thereof, it is desirable that the fluoropolymer-containing layer is the outermost layer of the polymer sheet for back sheets.

The fluoropolymer-containing weather-resistant layer may be formed by applying a coating liquid that contains fluoropolymer and the like to constitute the fluoropolymer-containing weather-resistant layer, onto the silicone-acrylic composite resin-containing weather-resistant layer followed by drying the coating layer. After dried, the layer may be cured by heating. The coating method and the solvent for the coating liquid are not specifically defined.

In the coating method, for example, usable is a gravure coater or a bar coater.

The solvent for use in the coating liquid may be water, or may also be an organic solvent such as toluene, methyl ethyl ketone, etc. One alone or two or more different types of solvents may be used either singly or as combined. Preferably, a binder such as a fluoropolymer or the like is dispersed in water to prepare a water-based coating liquid, and this is applied onto the weather-resistant layer. In this case, the proportion of water in the solvent is preferably at least 60% by mass, more preferably at least 80% by mass. When the amount of water is at least 60% by mass of the solvent contained in the coating liquid to form the fluoropolymer layer, then it is favorable since the environmental load could be reduced.

In the solar cell protective sheet of the invention, any additional layer may be further laminated on the weather-resistant layer of the fluoropolymer-containing layer. However, from the viewpoint of improving the durability of the polymer sheet for back sheets and from the viewpoint of weight reduction, thickness reduction and cost reduction thereof, it is desirable that the fluoropolymer-containing layer is the outermost layer of the solar cell protective sheet.

More preferably, in the solar cell protective sheet of the invention, the polyester support has the above-mentioned white layer on one side thereof and has the weather-resistant layer on the side opposite to the side of the polyester support that has the white layer thereon. Further, it is more desirable that, in the solar cell protective sheet of the invention, the polyester support has the white layer on one side thereof and has the fluoropolymer-containing weather-resistant layer further laminated on the silicone-acrylic composite resin-containing weather-resistant layer formed on the side opposite to the side of the polyester support that has the white layer thereon.

The solar cell protective sheet of the invention may have any other functional layer in addition to the polyester support and the polymer layer. As the functional layer, the sheet may have an undercoat layer.

### (Undercoat Layer)

The polymer sheet in the invention is arranged between the surface A of the polyester support and the white layer, and has an undercoat layer that contains at least one polymer selected from polyolefin resin, acrylic resin and polyester resin. The thickness of the undercoat layer is preferably at most 2 μm, more preferably from 0.05 μm to 2 μm, even more preferably from 0.1 μm to 1.5 μm. When the thickness is at most 2 μm, then the surface condition of the sheet could be kept good. When the thickness is at least 0.05 μm, then the layer could secure the necessary adhesiveness.

The undercoat layer contains at least one polymer selected from polyolefin resin, acrylic resin and polyester resin.

The polyolefin resin is, for example, preferably a polymer composed of polyethylene and acrylic acid or methacrylic acid. As the polyolefin resin, usable here are any commercially-available products. For example, there are mentioned Arrow Base SE-1013N, SD-1010, TC-4010, TD-4010 (all by Unitika), Hitec S3148, S3121, S8512 (all by Toho Chemical), Chemipearl S-120, S-75N, V100, EV210H (all by Mitsui Chemical), etc. Of those, preferred is use of Arrow Base SE-1013N (by Unitika).

As the acrylic resin, for example, preferred is a polymer containing polymethyl methacrylate, polymethyl methacrylate, etc. As the acrylic resin, usable here are commercially-available ones, including, for example, AS-563A (by Daicel FineChem).

The polyester resin is, for example, preferably polyethylene terephthalate (PET), polyethylene-2,6-naphthalate (PEN), etc. As the polyester resin, usable here are commercially-available ones, for example, including Vylonal MD-1245 (by Toyobo).

Of those polymers, especially preferred is a polymer comprising from 70 to 98 mol % of ethylene or propylene, from 0.1 to 15 mol % of acrylic acid or methacrylic acid, and from 0.1 to 20 mol % of a monomer selected from methyl acrylate, methyl methacrylate, ethyl acrylate and butyl acrylate; and more preferred is a polymer comprising from 80 to 96 mol % of ethylene or propylene, from 0.1 to 10 mol % of acrylic acid or methacrylic acid, and from 0.3 to 10 mol % of a monomer selected from methyl acrylate, methyl methacrylate, ethyl acrylate and butyl acrylate.

Of those, preferred is use of an acrylic resin or a polyolefin resin from the viewpoint of securing the adhesiveness of the layer to the polyester support and to the white layer. One alone or two or more different types of these polymers may be used here either singly or as combined. In case where two or more resins are used, preferred is a combination of an acrylic resin and a polyolefin resin.

Crosslinking Agent

In the polymer sheet of the invention, at least one of the undercoat layer and the silicone-acrylic composite resin-containing weather-resistant layer contains a crosslinking agent in an amount of from 0.5 to 30% by mass relative to the total binder in each polymer layer.

The crosslinking agent for use in the undercoat layer includes epoxy-type, isocyanate-type, melamine-type, carbodiimide-type and oxazoline-type crosslinking agents, etc. Of those, the crosslinking agent in the undercoat layer in the polymer sheet of the invention is preferably at least one crosslinking agent selected from a carbodiimide-type crosslinking agent, an oxazoline-type crosslinking agent and an isocyanate-type crosslinking agent. The description and the preferred ranges of the carbodiimide-type crosslinking agent and the oxazoline-type crosslinking agent for use in the undercoat layer are the same as the description and the preferred ranges of those for use in the white layer mentioned hereinabove. the isocyanate-type crosslinking agent is preferably a blocked isocyanate, more preferably a dimethylpyrazole-blocked isocyanate, and even more preferably a 3,5-dimethylpyrazole-blocked isocyanate. Preferred examples of the isocyanate-type crosslinking agent for use in the invention include Baxenden's Trixene series DP9C/214, and Baxenden's B17986.

The amount of the crosslinking agent is preferably from 0.5 to 30% by mass relative to the binder that constitutes the undercoat layer, more preferably from 5 to 20% by mass, even more preferably from 3% by mass to less than 15% by mass. In particular, when the amount of the crosslinking agent is at least 0.5% by mass, then the agent could provide a sufficient crosslinking effect while the strength and the adhesiveness of the undercoat layer could be kept good; and when at most 30% by mass, then the pot life of the coating liquid could be kept long, and when less than 15% by mass, then the surface condition of the layer could be bettered.

Preferably, the undercoat layer contains an anionic or nonionic surfactant. The range of the surfactant for use in the undercoat layer is the same as the range of the surfactant for use in the white layer mentioned above. Above all, preferred is use of a nonionic surfactant.

The amount of the surfactant, when added to the layer, is preferably from 0.1 to 10 mg/m², more preferably from 0.5 to 3 mg/m². When the amount of the surfactant is at least 0.1 mg/m², then a good layer could be formed while preventing cissing; and when at most 10 mg/m², the adhesiveness of the layer to the polyester support and to the white layer could be bettered.

Mat Agent

Preferably, the undercoat layer contains at least one mat agent. Containing a mat agent, the physical properties to be mentioned below and the lubricity of the polymer layer could be prevented from being worsened more (or that is, the kinematic friction factor of the layer could be prevented from increasing).

The mat agent is preferably a granular material, and may be any of an inorganic material or an organic material. For example, inorganic particles or polymer fine particles may be used. Concretely, as the inorganic particles, for example, preferred are particles of metal oxides such as titanium oxide, silica, alumina, zirconia, magnesia, etc.; as well as those of talc, calcium carbonate, magnesium carbonate, barium sulfate, aluminium hydroxide, kaolin, clay, etc.

As the polymer fine particles, for example, preferred are particles of an acrylic resin, a polystyrene resin, a polyurethane resin, a polyethylene resin, a benzoguanamine resin, an epoxy resin, etc. Also preferably, a latex may be added to the coating layer for forming the undercoat layer, and in such a case, the undercoat layer preferably contains the component derived from the latex.

Above all, in the invention, it is desirable that the undercoat layer contains at least any one of polymer fine particles and a latex-derived component, and preferably used are methyl methacrylate fine particles, ethyl acrylate latex, etc.

Preferably, the mean particle size of the mat agent is from 0.1 μm to 10 μm as the secondary particle size thereof, more preferably from 0.1 μm to 8 μm. When the secondary particle size of the mat agent is at most 10 μm, then aggregates would hardly form and a risk of cissing could be evaded in forming the polymer layer by coating and the embodiment is therefore favorable as readily providing a good surface condition. In case where a latex is used, it is desirable that the particle size in the coating liquid falls within the above range.

The mean particle size is a secondary particle size measured with a laser analyzing/scattering particle sizer LA950 (by Horiba Seisakusho).

The content of the mat agent in the undercoat layer is preferably within a range of from 0.3 mg/m² to 30 mg/m², more preferably from 10 mg/m² to 25 mg/m², even more preferably from 15 mg/m² to 25 mg/m². When the content of the mat agent is at most 30 mg/m², then aggregates would hardly form and a risk of cissing could be evaded in forming the polymer layer by coating and the embodiment is therefore favorable as readily providing a good surface condition.

Physical Properties of Undercoat Layer

Preferably, the elastic modulus and the breaking elongation of the undercoat layer each fall within a specific range.

Preferably, the elastic modulus of the undercoat layer is from 50 to 500 MPa, more preferably from 100 to 250 MPa.

Also preferably, the breaking elongation of the undercoat layer is from 5 to 150%, more preferably from 20 to 100%.

Method for Forming Undercoat Layer

The method for forming the undercoat layer and the solvent in the coating liquid to be used are not specifically defined.

In the coating method, for example, usable is a gravure coater or a bar coater.

The solvent for use in the coating liquid may be water, or may also be an organic solvent such as toluene, methyl ethyl ketone, etc. One alone or two or more different types of solvents may be used either singly or as combined. Preferably, a binder is dispersed in water to prepare a water-based coating liquid, and this is used for coating. In this case, the proportion of water in the solvent is preferably at least 60% by mass, more preferably at least 80% by mass.

The coating liquid may be applied onto the polyester support that has been stretched biaxially, or may be first applied onto the polyester support that has been stretched monoaxially, and then the thus-coated support may be further stretched in the direction different from the first stretching direction.

### <Method for Producing Solar Cell Protective Sheet>

The method for producing a solar cell protective sheet of the invention comprises applying a polymer layer-forming coating liquid that comprises a solvent or a dispersion medium of which the main component is water, and a binder, onto a polyester support of which the thickness is from 145 μm to 300 μm, of which the thermal shrinkage in an in-plane first direction after aged at 150° C. for 30 minutes is from 0.2 to 1.0% and of which the thermal shrinkage in a second direction perpendicular to the first direction is from −0.3 to 0.5%. Thus produced, the solar cell protective sheet is more excellent than any other laminate-type sheet in that the former is inexpensive.

The coating method is preferred in that it is simple and can form a uniform and thin film. As the coating method, for example, usable is any known coating method of suing a gravure coater, a bar coater or the like.

As the coating liquid for use in the coating method, known are a water-based coating liquid that uses water as the coating solvent, and a solvent-based liquid using an organic solvent such as toluene, methyl ethyl ketone, etc. From the viewpoint of the environmental load, a water-based coating liquid is prepared here, in which water is used as the coating solvent. Preferably, the method for producing a solar cell protective sheet of the invention includes a step of preparing the polymer layer-forming coating liquid by using water as the dispersion medium and by dispersing a binder in water. One alone or two or more different types of coating solvents may be used here either singly or as combined.

The coating liquid may be applied onto a biaxially-stretched polyester support, or may be first applied to a monoaxially-stretched polyester support and then the thus-coated support may be further stretched in the direction different from the first stretching direction. Further, the coating liquid may be applied to an unstretched polyester support and the thus-coated support may be stretched in two directions.

In the present invention, from the viewpoint that the polymer layer-forming coating liquid is applied to the support in such a manner that the polymer layer could be thick so as to have a dry thickness of at least 1 μm (more preferably a dry thickness of from 1.0 to 15.0 μm, even more preferably from 2.0 to 10.0 μm), it is desirable that the polymer layer-forming coating liquid is applied to the polyester support that has been stretched biaxially.

On the other hand, the production method of the invention may include a step of monoaxially stretching the polyester support before the step of laminating the polymer layer thereon, in which the polymer layer-laminating step may comprise a step of applying the polymer layer-forming coating liquid to the monoaxially-stretched polyester support and a step of stretching the coated polyester support and the coating film in the direction differing from the first stretching direction. In the case of coating the monoaxially-stretched film, the formed polymer layer could be thin, or that is, the thickness thereof could be from 0.03 μm to 1.5 μm or so. Also preferably, the second stretching direction is in the direction perpendicular to the first stretching direction.

In forming the polymer layer of the polymer sheet of the invention, it is desirable that the coated support is dried at a temperature of 80 to 220° C., more preferably at from 100° C. to 200° C. or so for a period of from 1 minute to 10 minutes, more preferably for from 1.5 minutes to 5 minutes or so.

As the production method for a solar cell protective sheet of the invention, preferred is an embodiment where an aqueous dispersion of a polymer having a (poly)siloxane structure in the molecular chain thereof and an aqueous dispersion of a lubricant (e.g., wax) are mixed to prepare an aqueous dispersion with the (poly)siloxane structure-having polymer particles and the lubricant particles dispersed therein, and the aqueous dispersion is applied onto the desired polyester support as the water-based coating liquid in the polymer layer forming step.

The details of the polyester support, and the polymer and other components constituting the coating liquid are as described above. Preferably, the solar cell protective sheet production method of the invention that uses the coating liquid includes a step of adding a white pigment to the polymer layer-forming coating liquid to prepare a white layer-forming coating liquid. Also preferably, the solar cell protective sheet production method of the invention includes a step of preparing a weather-resistant layer-forming coating liquid by the use of at least one of a fluoropolymer and a silicone-acrylic composite resin as the binder therein. Also preferably, the solar cell protective sheet production method of the invention includes a step of applying the white layer-forming coating liquid onto one side of a polyester support, and a step of applying the weather-resistant layer-forming coating liquid onto the side opposite to the side of the polyester support coated with the white layer-forming coating liquid.

In the polymer layer-forming step in the invention, preferably, the water-based coating liquid for forming the polymer layer as a white layer is applied to the surface of a polyester support via an undercoat layer, thereby forming the polymer layer serving as a white layer.

Here, the solvent or the dispersion medium that comprises water as the main ingredient thereof means that water accounts for at least 50% by mass of the solvent or the dispersion medium. In other words, the polymer layer-forming coating liquid is such a water-based coating liquid in which water accounts for at least 50% by mass relative to the total mass of the coating solvent contained therein, and is preferably a water-based coating liquid in which water accounts for at least 60% by mass. The water-based coating liquid is preferred from the viewpoint of environmental load, and when the proportion of water therein is at least 50% by mass, then the environmental load could be especially reduced. From the viewpoint of reducing the environmental load, the proportion of water in the coating liquid is preferably larger. More preferably, water accounts for at least 60% by mass of the solvent contained in the white layer-forming water-based composition. Even more preferably, water accounts for at least 90% by mass of the entire solvent.

In the solar cell protective sheet production method of the invention, it is desirable that the polymer layer-forming coating liquid is applied in such a manner that the dry thickness of the formed polymer layer could be at least 1 μm, and the preferred dry thickness of the polymer layer falls within the range of the preferred dry thickness of the polymer layer described hereinabove.

After the coating, the method may comprise a drying step of drying the coating film under a desired condition. The drying temperature in the drying step may be suitably selected depending on the composition of the coating liquid and the coating amount thereof.

In a solar cell that has a laminate structure of “transparent front substrate/element structure part/back sheet” where a transparent substrate arranged on the side on which sunlight is to fall (front substrate such as glass substrate or the like), an element structure part (including a solar cell element and a sealant to seal up the element) and a solar cell back sheet are laminated, the solar cell protective sheet of the invention may be applied to any of the front substrate and the back sheet. Here, the back sheet is the back protective sheet arranged on the side on which a front substrate is not positioned, when seen from the element structure part on the battery-side substrate.

In this description, the laminate structure of “transparent front substrate/element structure part”, in which an element structure part is positioned on the transparent support arranged on the side on which sunlight is to fall, is referred to as “battery-side substrate”.

### <Solar Cell Module>

The solar cell module of the invention comprises the already-mentioned solar cell protective sheet of the invention arranged as the solar cell back sheet therein. The solar cell module of the invention has the solar cell protective sheet of the invention described above, in which, therefore, the polymer layer formed by coating has a high film strength, has excellent scarring resistance to scratching, abrasion or the like, and has good light-fastness, heat resistance and moisture resistance. Accordingly, the solar cell module exhibits excellent weather resistance and exerts stable power generation capability for a long period of time.

Concretely, the solar cell module of the invention comprises a transparent substrate on which sunlight is to fall (front substrate such as glass substrate or the like), an element structure part arranged on the substrate and having a solar cell element and a sealant for sealing up the solar cell element, and the above-mentioned solar cell back sheet of the invention (including the solar cell protective sheet of the invention) arranged on the side opposite to the side of the element structure part on which the substrate is positioned, and has a laminate configuration of “transparent front substrate/element structure part/back sheet”. Concretely, the solar cell module is preferably so configured that the element structure part that has a solar cell element capable of converting sunlight energy to electric energy as provided therein is arranged between the transparent front substrate positioned on the side on which sunlight is to directly fall, and the above-mentioned solar cell back sheet of the invention, and between the front substrate and the back sheet, the solar cell element-containing element structure part (for example, solar cell) is sealed up and bonded with a sealant such as an ethylene-vinyl acetate (EVA) sealant.

FIG. 2 schematically shows one example of the configuration of the solar cell module of the invention. In the solar cell module 10, the solar cell element 20 capable of converting sunlight energy to electric energy is arranged between the transparent substrate 24 on which sunlight is to fall and the above-mentioned polymer sheet 12 of the invention, and the space between the substrate and the polymer sheet 12 is sealed up with the ethylene-vinyl acetate sealant 22. The polymer sheet of this embodiment comprises the first weather-resistant layer 3 that contains a silicone-acrylic composite resin as a polymer layer on one side of the polyester support 16, and the second weather-resistant layer 4 of a fluoropolymer layer that is positioned in contact with the first weather-resistant layer 3, and further has, on the other side thereof (on the side on which sunlight is to fall), the white layer 1 as a polymer via the undercoat layer 2.

The other parts than the solar cell module, the solar cell unit and the back sheet are described in detail, for example, in “Solar Power System Constitutive Materials” (supervised by Eiichi Sugimoto, published by Kogyo Chosakai Publishing, 2008).

The transparent substrate may be any one having optical transparency capable of transmitting light therethrough, and can be suitably selected from light-transmissive materials. From the viewpoint of power generation efficiency, preferred are those having a high light transmittance. As the substrates of the type, for example, preferably used here are glass substrate, transparent resins such as acrylic resins, etc.

For the solar cell element, herein employable are various known solar cell elements, for example, silicon-based elements such as single-crystal silicon, polycrystalline silicon, amorphous silicon; III-V group or II-VI Group compound semiconductor-based elements such as copper-indium-gallium-selenium, copper-indium-selenium, cadmium-tellurium, gallium-arsenic, etc.

### EXAMPLES

The invention is described more concretely with reference to the following Examples. In the following Examples, the material used, its amount and ratio, the details of the treatment and the treatment process may be suitably modified or changed not overstepping the spirit and the scope of the invention. Accordingly, the invention should not be limitatively interpreted by the Examples mentioned below. Unless otherwise specifically indicated, “part” is by mass.

### Example 1

### Formation of Polyester Support

### <1> Synthesis of Polyester

A slurry of 100 kg of high-purity terephthalic acid (by Mitsui Chemical) and 45 kg of ethylene glycol (by Nippon Shokubai) was sequentially fed into an esterification tank previously charged with about 123 kg of bis(hydroxyethyl)terephthalate and kept at a temperature of 250° C. and a pressure of 1.2×10⁵ Pa, taking 4 hours. After the addition, this was further esterified for 1 hour. Subsequently, 123 kg of the thus-obtained esterification product was transferred into a polycondensation tank.

Subsequently, ethylene glycol was added to the polycondensation tank in which the esterification product had been transferred, in an amount of 0.3% by mass of the polymer to be obtained. After this was stirred for 5 minutes, an ethylene glycol solution of cobalt acetate and manganese acetate was added thereto so that the cobalt element-equivalent amount thereof and the manganese element-equivalent amount thereof added could be 30 ppm and 15 ppm, respectively, of the polymer to be obtained. Further, this was stirred for 5 minutes, and then an ethylene glycol solution of 2% by mass of a titanium alkoxide compound was added thereto so that the titanium element-equivalent amount thereof added could be 5 ppm of the polymer to be obtained. After 5 minutes, an ethylene glycol solution of 10% by mass of ethyl diethylphosphonoacetate was added thereto so that the phosphorus element-equivalent amount thereof added could be 5 ppm of the polymer to be obtained. Next, with stirring the lower polymer at 30 rpm, the reaction system was gradually heated from 250° C. up to 285° C. and the pressure was lowered to 40 Pa. The time to the final temperature and that to the final pressure were both 60 minutes. After the reaction was continued as such for 3 hours, the reaction system was purged with nitrogen, and the pressure therein was restored to an ordinary pressure to thereby stop the polycondensation reaction. With that, the resulting polymer melt was strandwise jetted out into cold water, immediately cut into polymer pellets (diameter, about 3 mm; length, about 7 mm).

The titanium alkoxide compound used here is the titanium alkoxide compound (Ti content=4.44% by mass) produced in Example 1 in Paragraph [0083] in JP-A 2005-340616.

### <2> Solid-Phase Polymerization

The polymer pellets obtained in the above were put in a vacuum chamber kept at 40 Pa, and left therein at a temperature of 220° C. for 36 hours for solid-phase polymerization. After the solid-phase polymerization, the intrinsic viscosity IV and the carboxyl group content AV of the pellets were measured according to the methods mentioned below. The results are shown in Table 1 below.

### <3> Formation of Filmy Polyester Support

After the solid-phase polymerization as in the above, the pellets were melt-extruded through a double-screw melt extruder at 280° C. and cast onto a metal drum to produce an unstretched base having a thickness of about 2.5 mm. Subsequently, this was stretched in MD (machine direction) at 90° C. by 3.4 times. Further, at 120° C., this was stretched in TD (transverse direction) by 4.5 times, then heat-treated at a film surface temperature of 200° C. for 15 seconds, and thereafter thermally relaxed at 190° C. in MD/TD at the MD/TD relaxation ratio shown in Table 1. Thus obtained was a biaxially-stretched polyethylene terephthalate substrate S-1 having the thickness shown in Table 1 below (hereinafter this may be referred to as “polyester support S-1”).

The intrinsic viscosity IV, the carboxyl group content AV, the tan δ peak and the thermal shrinkage in MD and TD of the polyester support S-1 were measured according to the methods mentioned below. The results are shown in Table 1 below.

Measurement of Physical Data of Starting Polyester and Polyester Support

### (Intrinsic Viscosity)

The intended polyester was ground into powder, and dissolved in a mixed solvent of 1,2,2-tetrachloroethane/phenol (=⅔ [ratio by mass]) to be 0.01 g/ml, and using an Ubbelohde viscometer (AVL-6C, by Asahi Kasei Technosystems), the sample was measured at a temperature of 25° C. As the math formula for the intrinsic viscosity, the following equation was used. The sample dissolution took 30 minutes at 120° C.

ηsp/C=[η]+K[η]²·C

In this, ηsp=(solution viscosity/solvent viscosity)−1; C is the polymer weight dissolved in 100 ml of the solvent (in this measurement, this is 1 g/100 ml); and K is the Huggins constant (0.343).

### (Carboxyl Group Content)

The carboxyl group content (AV) was measured according to the method described in H. A. Pohl, Anal. Chem. 26 (1954) 2145. Concretely, the intended polyester film was ground into powder and then dried in a vacuum drier at 60° C. for 30 minutes. Next, immediately after the drying, 0.1000 g of the polyester was metered, 5 ml of benzyl alcohol is added thereto, and stirred with heating for dissolution at 205° C. for 2 minutes. The solution was cooled, then completely dissolved in 15 ml of/chloroform (=⅔, ratio by volume), and using phenol red as an indicator, the sample was titered with an alkali standard liquid (0.0125 N KOH-benzyl alcohol/methanol mixed solution) to the neutralization point (pH=7.3±0.1). From the titered data, the content was calculated.

### (Tan δ Peak)

The peak of tan δ was measured as follows: After conditioned at 25° C. and at a relative humidity of 60% for 2 hours or more, the sample was analyzed with a commercially-available dynamic viscoelastometer (Vibron: DVA-225 (by ITK)) at a heating speed of 2° C./min within a measurement temperature range of from 30° C. to 200° C. and at a frequency of 1 Hz.

### (MD and TD Thermal Shrinkage)

The obtained polyester support S-1 was conditioned in an atmosphere at 25° C. and at a relative humidity of 60% for 24 hours. After conditioned, the sample was cut with a razor to form two parallel linear cuts at an interval of about 30 cm on the surface thereof. The distance between the two cuts was measured to be L⁰. The thus-cut sample was heat-treated by aging at 150° C. for 30 minutes. After the heat treatment, the sample was conditioned in an atmosphere at 25° C. and at a relative humidity of 60% for 24 hours, and the distance L¹ between the two cuts was measured.

From the data L⁰ and L¹, the thermal shrinkage was calculated according to the following equation:

Thermal Shrinkage [%]=(L⁰−L¹)/L⁰×100

The thermal shrinkage was measured and calculated in both MD (machine direction) and TD (transverse direction) of the polyester support. The mean value is referred to as the thermal shrinkage of the polyester. The unit of the thermal shrinkage is [%], and the positive numerical value indicates shrinkage while the negative numerical value indicates contraction.

Formation of Undercoat Layer

### (1) Preparation of Undercoat Layer-Forming Coating Liquid

The constituent components mentioned below were mixed to prepare an undercoat layer-forming coating liquid.

### <Composition of Coating Liquid>

Polyolefin binder (Arrow Base SE-1013N, by Unitika, concentration 20% by mass) 35.6 parts by mass
Acrylic binder (AS-563A, by Daicel Finechem, concentration 28% by mass) 25.7 parts by mass
PMMA fine particles (MP-1000, by Soken Chemical, concentration 5% by mass) 10.0 parts by mass
Nonionic surfactant (Naroacty CL95, by Sanyo Chemical, concentration 1% by mass) 15.0 parts by mass
Carbodiimide-type crosslinking agent (Carbodilite V-02-L2, by Nisshinbo, concentration 20% by mass) 12.3 parts by mass
Oxazoline-type crosslinking agent (Epocross WS-700, by Nippon Shokubai, concentration 25% by mass) 3.0 parts by mass
Distilled water 898.4 parts by mass

### (2) Formation of Undercoat Layer

One surface of the polyester support S-1 was corona-treated under the condition mentioned below.

Gap clearance between electrode and dielectric roll: 1.6 mm

Treatment frequency: 9.6 kHz

Treatment speed: 20 m/min

Treatment intensity: 0.375 kV·A·min/m²

Next, the underlayer-forming coating liquid was applied onto the corona-treated surface of the polyester support S-1 in such a manner that the binder coating amount could be 0.12 g/m², and then dried at 180° C. for 2 minutes to form an undercoat layer.

Formation of White Layer

### (1) Preparation of Titanium Dioxide Dispersion

Using a Dyno Mill disperser, titanium dioxide was dispersed to have a mean particle size of 0.42 μm, thereby preparing a titanium dioxide dispersion. The mean particle size of titanium dioxide was measured using Honeywell's Microtrack FRA.

### (Composition of Titanium Dioxide Dispersion)

| | |
|---|---|
| Titanium dioxide (Taipake CR-95, by Ishihara | 455.8 parts by mass |
| Sangyo, powder) | |
| Aqueous PVA solution (PVA-105, by Kureha, | 227.9 parts by mass |
| concentration 10% by mass) | |
| Dispersing medium (Demol EP, by Kao, | 5.5 parts by mass |
| concentration 25% by mass) | |
| Distilled water | 310.8 parts by mass |

### (2) Preparation of Coating Liquid for White Layer

The following components were mixed to prepare a coating liquid for white layer.

### <Composition of Coating Liquid>

| | |
|---|---|
| Titanium dioxide dispersion mentioned above | 298.5 parts by mass |
| Polyolefin binder (Arrow Base SE-1013N, by | 568.7 parts by mass |
| Unitika, concentration 20% by mass) | |
| Nonionic surfactant (Naroacty CL95, by Sanyo | 23.4 parts by mass |
| Kasei, concentration 1% by mass) | |
| Oxazoline-type crosslinking agent (Epocross | 58.4 parts by mass |
| WS-700, by Nippon Shokubai, concentration | |
| 25% by mass) | |
| Distilled water | 51.0 parts by mass |

### (3) Formation of White Layer

Thus obtained, the polymer layer 1-forming coating liquid was applied onto the undercoat layer on the polyester support S-1 in such a manner that the binder coating amount could be 4.7 g/m² and the titanium dioxide coating amount could be 5.6 g/m², and then dried at 170° C. for 2 minutes to form a white layer.

The volume fraction of the pigment in the polymer layer 1 was calculated according to the following equation, considering that the specific gravity of titanium dioxide (rutile type) be 4.27 and the specific gravity of the binder in the polymer layer 1 be 1.00.

Pigment Volume Fraction=(5.6/4.27)/{(4.7/1.00)+(5.6/4.27)}×100(%)=22(%)

Formation of Silicone/Acrylic Composite Resin-Containing Weather-Resistant Layer

### (1) Preparation of Coating Liquid for Formation of Silicone/Acrylic Composite Resin-Containing Weather-Resistant Layer

The constituent components mentioned below were mixed to prepare a coating liquid for forming a silicone/acrylic composite resin-containing weather-resistant layer.

### <Composition of Coating Liquid>

| | |
|---|---|
| Silicone binder (Ceranate WSA1070, by DIC, | 396.5 parts by mass |
| concentration 38% by mass) | |
| Titanium dispersion (same as in polymer | 493.9 parts by mass |
| layer 1) | |
| Nonionic surfactant (Naroacty CL95, by | 15.0 parts by mass |
| Sanyo Chemical, concentration 1% by mass) | |
| Carbodiimide-type crosslinking agent | 49.0 parts by mass |
| (Carbodilite V-02-L2, by Nisshinbo, | |
| concentration 20% by mass) | |
| Oxazoline-type crosslinking agent (Epocross | 16.8 parts by mass |
| WS-700, by Nippon Shokubai, concentration | |
| 25% by mass) | |
| Distilled water | 28.8 parts by mass |

### (2) Formation of Silicone/Acrylic Composite Resin-Containing Weather-Resistant Layer

The other side (hereinafter this may be referred to as back side) opposite to the side of the polyester support S-1 on which the white layer had been formed was corona-treated under the condition mentioned below.

Gap clearance between electrode and dielectric roll: 1.6 mm

Treatment frequency: 9.6 kHz

Treatment speed: 20 m/sec

Treatment intensity: 0.375 kV·A·min/m²

Next, the coating liquid for formation of silicone/acrylic composite resin-containing weather-resistant layer was applied onto the corona-treated surface of the back side of the polyester support S-1 in such a manner that the binder coating amount could be 5.1 mg/m² and the titanium dioxide coating amount could be 7.6 mg/m², and then dried at 175° C. for 2 minutes to thereby form a silicone/acrylic composite resin-containing weather-resistant layer.

Formation of Fluoropolymer-Containing Weather-Resistant Layer

### (1) Preparation of Coating Liquid for Formation of Fluoropolymer-Containing Weather-Resistant Layer

The following components were mixed to prepare a coating liquid for formation of a fluoropolymer-containing weather-resistant layer.

### (Composition of Coating Liquid for Formation of Fluoropolymer-Containing Weather-Resistant Layer)

| | |
|---|---|
| Fluorine-containing binder (Obbligato SW0011F, by | 345.0 parts by mass |
| AGC Coat-tech, concentration 36% by mass) | |
| Colloidal silica (SnowtexUP, by Nissan Chemical, | 3.9 parts by mass |
| concentration 20% by mass) | |
| Silane coupling agent (TSL8340, by Momentive | 78.5 parts by mass |
| Performance Material, concentration 1% by mass) | |
| Organic lubricant (Chemipearl W950, by Mitsui | 207.6 parts by mass |
| Chemical, concentration 5% by mass) | |
| Nonionic surfactant (Naroacty CL95, by Sanyo | 60.0 parts by mass |
| Chemical, concentration 1% by mass) | |
| Carbodiimide-type crosslinking agent (Carbodilite | 62.3 parts by mass |
| V-02-L2, by Nisshinbo, concentration 20% by mass) | |
| Distilled water | 242.8 parts by mass |

### (2) Formation of Fluoropolymer-Containing Weather-Resistant Layer

The fluoropolymer-containing weather-resistant layer-forming coating liquid was applied onto the silicone/acrylic composite resin-containing weather-resistant layer formed on the support in the above, in such a manner that the binder coating amount could be 1.3 g/m², and dried at 175° C. for 2 minutes to form a fluoropolymer-containing weather-resistant layer.

As in the above, the undercoat layer and the white layer were arranged on the polyester support in that order on the side nearer to the support, and on the opposite side B, the silicone/acrylic composite resin-containing weather-resistant layer and the fluoropolymer-containing weather-resistant layer were arranged in that order nearer on the side nearer to the support, thereby constructing a solar cell protective sheet of Example 1.

### (Evaluation)

The solar cell protective sheet produced in Examples and Comparative Examples was evaluated in the manner mentioned below. The evaluation results are shown in Table 1 below.

### (Adhesiveness to Tape)

Using a razor, the surface of the white layer or the surface of the weather-resistant layer (the surface of the fluoropolymer-containing weather-resistant layer) of the solar cell protective sheet was cross-cut at intervals of 3 mm to form 6 line cuts each in the lengthwise direction and the widthwise direction thereof. Next, a Mylar tape having a width of 20 mm was stuck onto it, and rapidly peeled in the direction of 90 degrees.

The number of the peeled cross-cuts was counted and the sample was ranked as follows:

5: No cross-cut peeled at all.
4: The number of the peeled cross-cuts was zero, but the cut edges slightly peeled.
3: The number of the peeled cross-cuts was less than 1.
2: The number of the peeled cross-cuts was from 1 to less than 5.
1: The number of the peeled cross-cuts was 5 or more.

Those grouped in the ranks 3 to 5 are practicable.

(Adhesiveness to Tape after PCT)

Before cut with a razor, the solar cell protective sheet was subjected to wet heat treatment (PCT) in an atmosphere at 120° C. and at a relative humidity of 100% for 105 hours, and then tested according to the above-mentioned tape adhesiveness test.

(Retention of Fracture Elongation after PCT)

The obtained solar cell protective sheet was tested according to the following measurement method to determine the fracture elongation data L⁰ and L¹ thereof. Based on the data, the retention of fracture elongation (%) of the sample was calculated according to the following equation. Those having a retention of fracture elongation of at least 50% are practicable.

Retention of Fracture Elongation (%)=(L¹/L⁰)×100

### <Measurement of Fracture Elongation>

The solar cell protective sheet on which the coating layers shown in Table 1 below had been formed was cut into a size of width 10 mm×length 200 mm, thereby preparing test sample pieces A and B. The sample piece A was conditioned in an atmosphere at 25° C. and at a relative humidity of 60% for 24 hours, and then tested according to a tensile test with a tensilon (Orientec's RTC-1210A). The length of the sample piece to be pulled was 10 cm, and the pulling rate was 20 mm/min. The fracture elongation of the sample A in this test is referred to as L⁰.

Separately, the sample B was subjected to wet heat treatment (PCT) in an atmosphere at 120° C. and at a relative humidity of 100% for 105 hours, and then tested according to the same tensile test as that for the sample piece A. The fracture elongation of the sample B in this test is referred to as L¹.

TABLE 1

| | | | | | | Configuration of Solar Cell Protective Sheet | | | | | |
|---|---|---|---|---|---|---|---|---|---|---|---|
| | Production of Polyester Support | | | | | Characteristics of Polymer Support before Coated | | | | | |
| | | Starting | Starting | MD | TD | | | | | MD | TD |
| | | Material | Material | Relaxation | Relaxation | | | Tanδ Peak | Support | Thermal | Thermal |
| | | IV | AV | Ratio | Ratio | Film IV | Film AV | Temperature | Thickness | Shrinkage | Shrinkage |
| | Resin | (dl/g) | (eg/t) | (%) | (%) | (dl/g) | (eg/t) | (° C.) | (μm) | (%) | (%) |
| Example 1 | PET | 0.785 | 10.5 | 5.0 | 11.0 | 0.760 | 13.5 | 126.0 | 145 | 0.6 | 0.3 |
| Example 2 | PET | 0.785 | 10.5 | 5.0 | 11.0 | 0.760 | 13.5 | 126.0 | 180 | 0.6 | 0.3 |
| Example 3 | PET | 0.785 | 10.5 | 5.0 | 11.0 | 0.760 | 13.5 | 126.0 | 210 | 0.6 | 0.3 |
| Example 4 | PET | 0.785 | 10.5 | 5.0 | 11.0 | 0.760 | 13.5 | 126.0 | 240 | 0.6 | 0.3 |
| Example 5 | PET | 0.785 | 10.5 | 5.0 | 11.0 | 0.760 | 13.5 | 126.0 | 250 | 0.6 | 0.3 |
| Example 6 | PET | 0.785 | 10.5 | 5.0 | 11.0 | 0.760 | 13.5 | 126.0 | 270 | 0.6 | 0.3 |
| Example 7 | PET | 0.785 | 10.5 | 5.0 | 11.0 | 0.760 | 13.5 | 126.0 | 300 | 0.6 | 0.3 |
| Example 8 | PET | 0.785 | 10.5 | 4.0 | 10.5 | 0.760 | 13.5 | 126.2 | 240 | 1.0 | 0.5 |
| Example 9 | PET | 0.785 | 10.5 | 6.0 | 12.0 | 0.760 | 13.5 | 125.8 | 240 | 0.2 | 0.0 |
| Example 10 | PET | 0.785 | 10.5 | 4.0 | 11.0 | 0.760 | 13.5 | 126.0 | 240 | 1.0 | 0.3 |
| Example 11 | PET | 0.785 | 10.5 | 4.5 | 11.0 | 0.760 | 13.5 | 125.8 | 240 | 0.8 | 0.3 |
| Example 12 | PET | 0.785 | 10.5 | 5.5 | 11.0 | 0.760 | 13.5 | 125.6 | 240 | 0.3 | 0.3 |
| Example 13 | PET | 0.785 | 10.5 | 6.0 | 11.0 | 0.760 | 13.5 | 125.5 | 240 | 0.2 | 0.3 |
| Example 14 | PET | 0.785 | 10.5 | 5.0 | 10.5 | 0.760 | 13.5 | 126.2 | 240 | 0.6 | 0.5 |
| Example 15 | PET | 0.785 | 10.5 | 5.0 | 12.0 | 0.760 | 13.5 | 126.0 | 240 | 0.6 | 0.0 |
| Example 16 | PET | 0.785 | 10.5 | 5.0 | 13.5 | 0.760 | 13.5 | 125.8 | 240 | 0.6 | −0.1 |
| Example 17 | PET | 0.785 | 10.5 | 5.0 | 15.0 | 0.760 | 13.5 | 125.5 | 240 | 0.6 | −0.3 |
| Example 18 | PET | 0.785 | 10.5 | 5.0 | 11.0 | 0.760 | 13.5 | 126.0 | 240 | 0.6 | 0.3 |
| Example 19 | PET | 0.785 | 10.5 | 5.0 | 11.0 | 0.760 | 13.5 | 126.0 | 240 | 0.6 | 0.3 |
| Example 20 | PET | 0.650 | 20.0 | 4.0 | 10.0 | 0.620 | 24.0 | 125.5 | 240 | 0.6 | 0.3 |
| Example 21 | PET | 0.650 | 20.0 | 3.0 | 9.5 | 0.620 | 24.0 | 126.0 | 240 | 1.0 | 0.5 |
| Example 22 | PET | 0.650 | 20.0 | 5.0 | 11.0 | 0.620 | 24.0 | 125.2 | 240 | 0.2 | 0.0 |
| Example 23 | PEN | 0.650 | 20.0 | 6.0 | 14.0 | 0.620 | 24.0 | 171.0 | 240 | 0.6 | 0.3 |
| Example 24 | PBT | 0.650 | 20.0 | 6.0 | 14.0 | 0.620 | 24.0 | 115.2 | 240 | 0.6 | 0.3 |
| Comparative Example 1 | PET | 0.785 | 10.5 | 5.0 | 11.0 | 0.760 | 13.5 | 126.0 | 140 | 0.6 | 0.3 |
| Comparative Example 2 | PET | 0.785 | 10.5 | 5.0 | 11.0 | 0.760 | 13.5 | 126.0 | 310 | 0.6 | 0.3 |
| Comparative Example 3 | PET | 0.785 | 10.5 | 2.0 | 5.0 | 0.760 | 13.5 | 126.4 | 240 | 1.5 | 1.5 |
| Comparative Example 4 | PET | 0.785 | 10.5 | 3.0 | 7.0 | 0.760 | 13.5 | 126.3 | 240 | 1.1 | 1.1 |
| Comparative Example 5 | PET | 0.785 | 10.5 | 3.0 | 9.0 | 0.760 | 13.5 | 126.2 | 240 | 1.1 | 0.6 |
| Comparative Example 6 | PET | 0.785 | 10.5 | 6.5 | 11.5 | 0.760 | 13.5 | 125.6 | 240 | 0.1 | 0.1 |
| Comparative Example 7 | PET | 0.650 | 20.0 | 2.0 | 8.0 | 0.760 | 13.5 | 126.0 | 240 | 1.1 | 0.6 |
| Comparative Example 8 | PET | 0.650 | 20.0 | 6.0 | 11.0 | 0.620 | 25.0 | 125.0 | 240 | 0.1 | 0.1 |
| Comparative Example 9 | PEN | 0.650 | 20.0 | 3.0 | 9.0 | 0.620 | 25.0 | 171.5 | 240 | 1.1 | 0.6 |

| | Configuration of | | | | | | |
|---|---|---|---|---|---|---|---|
| | Solar Cell | | Evaluation of Solar Cell Protective Sheet | | | | |
| | Protective Sheet | | before wet heat test | | after wet heat test | | |
| | Coating Amount | | | Weather- | | Weather- | |
| | | Weather- | | Resistant | | Resistant | Retention of |
| | White | Resistant | White Layer | Layer | White Layer | Layer | Fracture |
| | Layer | Layer | Adhesiveness | Adhesiveness | Adhesiveness | Adhesiveness | Elongation |
| | (μm) | (μm) | to Tape | to Tape | to Tape | to Tape | (%) |
| Example 1 | 5 | 8 | 5 | 5 | 4 | 4 | 97 |
| Example 2 | 5 | 8 | 5 | 5 | 4 | 5 | 97 |
| Example 3 | 5 | 8 | 5 | 5 | 5 | 5 | 97 |
| Example 4 | 5 | 8 | 5 | 5 | 5 | 5 | 97 |
| Example 5 | 5 | 8 | 5 | 5 | 5 | 5 | 97 |
| Example 6 | 5 | 8 | 5 | 5 | 5 | 4 | 97 |
| Example 7 | 5 | 8 | 4 | 4 | 3 | 3 | 97 |
| Example 8 | 5 | 8 | 4 | 5 | 3 | 3 | 100 |
| Example 9 | 5 | 8 | 4 | 4 | 3 | 4 | 90 |
| Example 10 | 5 | 8 | 4 | 5 | 3 | 3 | 100 |
| Example 11 | 5 | 8 | 5 | 5 | 4 | 4 | 98 |
| Example 12 | 5 | 8 | 5 | 5 | 4 | 4 | 95 |
| Example 13 | 5 | 8 | 5 | 4 | 3 | 3 | 92 |
| Example 14 | 5 | 8 | 4 | 5 | 5 | 4 | 97 |
| Example 15 | 5 | 8 | 5 | 5 | 5 | 5 | 96 |
| Example 16 | 5 | 8 | 5 | 5 | 4 | 4 | 95 |
| Example 17 | 5 | 8 | 4 | 5 | 3 | 4 | 95 |
| Example 18 | 5 | none | 5 | — | 5 | — | 97 |
| Example 19 | none | 8 | — | 5 | — | 5 | 97 |
| Example 20 | 5 | 8 | 5 | 5 | 4 | 4 | 30 |
| Example 21 | 5 | 8 | 4 | 4 | 3 | 3 | 35 |
| Example 22 | 5 | 8 | 4 | 4 | 3 | 3 | 25 |
| Example 23 | 5 | 8 | 5 | 5 | 4 | 4 | 50 |
| Example 24 | 5 | 8 | 4 | 4 | 3 | 3 | 100 |
| Comparative Example 1 | 5 | 8 | 3 | 3 | 2 | 2 | 97 |
| Comparative Example 2 | 5 | 8 | 2 | 2 | 1 | 1 | 97 |
| Comparative Example 3 | 5 | 8 | 2 | 2 | 1 | 1 | 100 |
| Comparative Example 4 | 5 | 8 | 2 | 2 | 1 | 1 | 100 |
| Comparative Example 5 | 5 | 8 | 3 | 3 | 1 | 2 | 100 |
| Comparative Example 6 | 5 | 8 | 3 | 3 | 2 | 2 | 90 |
| Comparative Example 7 | 5 | 8 | 3 | 3 | 1 | 2 | 30 |
| Comparative Example 8 | 5 | 8 | 3 | 3 | 2 | 2 | 30 |
| Comparative Example 9 | 5 | 8 | 3 | 3 | 1 | 1 | 100 |

From the above Table 1, it is known that the solar cell protective sheet of the invention has good adhesiveness to both the polyester support and the polymer layer throughout before and after wet heat aging. In addition to the above-mentioned tests, a sample prepared by forming only the first layer, silicone/acrylic composite resin-containing weather-resistant layer alone as the weather-resistant layer was tested according to the same tape adhesiveness test, and, as a result, the results tended to be the same as the results of the test of the sample additionally having the second layer, fluoropolymer-containing weather-resistant layer.

Further, the residual solvent amount in the solar cell protective sheet of the invention was measured by analyzing a 7 mm×35 mm sample thereof through gas chromatography (with GC-18A by Shimadzu). As a result, it was known that the residual solvent amount in the solar cell protective sheet of the invention was at most 0.01% by weight in every case. The polyester support was cut off from the solar cell protective sheet of the invention to prepare a sample of polymer layer alone of 7 mm×35 mm. This was analyzed through gas chromatography (with GC-18A by Shimadzu). As a result, it was known that the residual solvent amount in polymer layer in the solar cell protective sheet of the invention was at most 0.01% by weight in every case.

On the other hand, from Comparative Example 1, it is known that, when the thickness of the polyester support is lower than the lower limit of the range in the invention, then the adhesiveness between the polyester support and the polymer layer after wet heat aging lowered. From Comparative Example 2, it is known that, when the thickness of the polyester support is higher than the higher limit of the range in the invention, then the adhesiveness between the polyester support and the polymer layer before wet heat aging and after wet heat aging lowered. From Comparative Examples 3 and 4, it is known that, when the thermal shrinkage in two directions of the polyester support before coated with the coating layers is higher than the higher limit of the range in the invention, then the adhesiveness between the polyester support and the polymer layer before wet heat aging and after wet heat aging lowered. From Comparative Examples 5, 7 and 9, it is known that, when the thermal shrinkage in one direction of the polyester support before coated with the coating layers is higher than the higher limit of the range in the invention, then the adhesiveness between the polyester support and the polymer layer after wet heat aging lowered. From Comparative Examples 6 and 8, it is known that, when the thermal shrinkage in one direction of the polyester support before coated with the coating layers is lower than the lower limit of the range in the invention, then the adhesiveness between the polyester support and the polymer layer after wet heat aging lowered.

(Evaluation of Shape Before and after Wet Heat Aging)

The solar cell protective sheet of Examples mentioned above was subjected to wet heat treatment in an environment at 120° C. and at a relative humidity of 100% for 105 hours, and checked in a dark room for deformation of the shape of the sheet before and after wet heat aging, based on the presence or absence of deformation of the reflected images of two fluorescent lamps arranged in parallel to each other above the sheet. As a result, as compared with the film before wet heat aging, the distortion of the reflected lamp image was on the same level in every case, and no film deformation was recognized.

On the other hand, a film of Example 1 in JP-T 2010-519742, having an EVA layer of 100 μm, a PET layer of about 125 μm and a fluoropolymer-containing coating layer of 15 μm was checked in the same manner as above for deformation before and after wet heat aging. As a result, it was visually confirmed that the distortion greatly increased as compared with the film before wet heat aging. The comparative sample was further checked while the above-mentioned solar cell protective sheet of Examples after wet heat aging was laid adjacent thereto, and it was also visually confirmed that the distortion on the comparative sheet greatly increased.

### Example 101

### (3) Formation of Solar Cell Module

A reinforce glass plate having a thickness of 3 mm, an EVA sheet (Mitsui Chemical Fabro's SC50B), a crystalline solar cell, an EVA sheet (Mitsui Chemical Fabro's SC50B) and the solar cell protective sheet of Example 101 were laminated in that order and in such a manner that the white layer of the solar cell protective sheet could be in direct contact with the EVA sheet, and hot-pressed with a vacuum laminator (Nisshinbo's Vacuum Laminator) for sealing with EVA. The sealing method is as follows:

### <Sealing Method>

Using a vacuum laminator, the sample was vacuumed at 128° C. for 3 minutes and the pressed for 2 minutes for pre-sealing. Subsequently, this was heated in a dry oven at 150° C. for 30 minutes for final sealing.

As in the above, a crystalline solar cell module of Example 101 was produced. Thus produced, the solar cell module was left in an environment at 120° C. and at a relative humidity of 100% for 70 hours, and the driven for power generation. As a result, the module exhibited good power generation performance as a solar cell.

### Examples 102 to 124

Solar cell modules were produced in the same manner as in Example 101, except that the solar cell protective sheet produced in Examples 2 to 24 was used in place of the solar cell protective sheet produced in Example 1.

In the same manner as in Example 101, the thus-obtained solar cell modules were driven for power generation, and as a result, all the modules exhibited good power generation performance as a solar cell.

### REFERENCE SIGNS LIST

1 White Layer
2 Undercoat Layer
3 First Weather-Resistant Layer (silicone/acrylic composite resin layer)
4 Second Weather-Resistant Layer (fluoropolymer layer)
12 Solar Cell Protective Sheet
16 Polyester Support
22 Sealant
20 Solar Cell Element
24 Transparent Front Substrate (reinforced glass)
10 Solar Cell Module

While the present invention has been described in detail and with reference to specific embodiments thereof, it will be apparent to one skilled in the art that various changes and modifications can be made therein without departing from the spirit and scope thereof.

The present disclosure relates to the subject matter contained in International Application No. PCT/JP2012/067946, filed Jul. 13, 2012; and Japanese Application No. 2011-155558, filed Jul. 14, 2011, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A solar cell protective sheet comprising:
a polyester support having a thickness of from 145 μm to 300 μm, a thermal shrinkage in an in-plane first direction after aged at 150° C. for 30 minutes of from 0.2 to 1.0% and a thermal shrinkage in a second direction perpendicular to the first direction of from −0.3 to 0.5%, and
a polymer layer arranged on at least one side of the polyester support and having a residual solvent amount of at most 0.1% by mass.

2. The solar cell protective sheet according to claim 1, wherein the thickness of the polymer layer is at least 1 μm.

3. The solar cell protective sheet according to claim 1, wherein the in-plane first direction of the polyester support is the film longitudinal direction.

4. The solar cell protective sheet according to claim 1, wherein the polyester support is a polyethylene terephthalate support.

5. The solar cell protective sheet according to claim 1, wherein the terminal carboxyl group content in the polyester support is at most 20 eq/t.

6. The solar cell protective sheet according to claim 1, wherein the peak of tan δ of the polyester support, as measured with a dynamic viscoelastometer, is at 123° C. or higher.

7. The solar cell protective sheet according to claim 1, wherein the intrinsic viscosity IV of the polyester support is at least 0.65 dl/g.

8. The solar cell protective sheet according to claim 1, which has, as the polymer layer, a white layer containing a white pigment and a binder.

9. The solar cell protective sheet according to claim 8, wherein the white layer is formed by coating.

10. The solar cell protective sheet according to claim 9, wherein the white layer contains, as the binder, a water-based latex-derived binder.

11. The solar cell protective sheet according to claim 1, wherein the binder in the white layer is a copolymer containing an olefin component and at least any one of an acrylate component and an acid anhydride component.

12. The solar cell protective sheet according to claim 1, which has, as the polymer layer, a weather-resistant layer containing at least one of a fluoropolymer and a silicone-acrylic composite resin.

13. The solar cell protective sheet according to claim 12, wherein the weather-resistant layer is formed by coating.

14. The solar cell protective sheet according to claim 12, wherein the fluoropolymer or the silicone-acrylic composite resin in the weather-resistant layer is a water-based latex-derived binder.

15. The solar cell protective sheet according to claim 1, wherein the weather-resistant layer is arranged in contact with the polyester support.

16. The solar cell protective sheet according to claim 1, which has the white layer on one side of the polyester support and has the weather-resistant layer on the other side opposite to the side of the polyester support having the white layer thereon.

17. The solar cell protective sheet according to claim 16, wherein the weather-resistant layer comprises a first weather-resistant layer containing a silicone-acrylic composite resin and, as arranged on the first weather-resistant layer, a second weather-resistant layer containing a fluoropolymer.

18. A method for producing a solar cell protective sheet, comprising:
applying a polymer layer-forming coating liquid that comprises a solvent or a dispersion medium of which the main component is water, and a binder, onto a polyester support, wherein the polyester support has a thickness of from 145 μm to 300 μm, a thermal shrinkage in an in-plane first direction after aged at 150° C. for 30 minutes of from 0.2 to 1.0%, and a thermal shrinkage in a second direction perpendicular to the first direction of from −0.3 to 0.5%.

19. The method for producing a solar cell protective sheet according to claim 18, wherein the polymer layer-forming coating liquid is applied so that the dry thickness of the polymer layer could be at least 1 μm.

20. The method for producing a solar cell protective sheet according to claim 18, wherein the in-plane first direction of the polyester support is the film-conveying direction.

21. The method for producing a solar cell protective sheet according to claim 18, wherein the polyester support is a polyethylene terephthalate support.

22. The method for producing a solar cell protective sheet according to claim 18, wherein the terminal carboxyl group content in the polyester support is at most 20 eq/t.

23. The method for producing a solar cell protective sheet according to claim 18, wherein the peak of tan δ of the polyester support, as measured with a dynamic viscoelastometer, is at 123° C. or higher.

24. The method for producing a solar cell protective sheet according to claim 18, wherein the intrinsic viscosity IV of the polyester support is at least 0.65 dl/g.

25. The method for producing a solar cell protective sheet according to claim 18, comprising adding a white pigment to the polymer layer-forming coating liquid to prepare a white layer-forming coating liquid.

26. The method for producing a solar cell protective sheet according to claim 25, wherein the binder in the white layer-forming coating liquid is a copolymer containing an olefin component and at least any one of an acrylate component and an acid anhydride component.

27. The method for producing a solar cell protective sheet according to claim 18, comprising using, as the binder, at least any one of a fluoropolymer and a silicone-acrylic composite resin to prepare a weather-resistant layer-forming coating liquid.

28. The method for producing a solar cell protective sheet according to claim 18, comprising using water as the dispersion medium and using a water-based binder as the binder, followed by dispersing the water-based binder in water to thereby prepare the polymer layer-forming coating liquid.

29. The method for producing a solar cell protective sheet according to claim 27, comprising applying the white layer-forming coating liquid onto one side of the polyester support, and
applying the weather-resistant layer-forming liquid onto the other side opposite to the side of the polyester support coated with the white layer-forming coating liquid.

30. The method for producing a solar cell protective sheet according to claim 29, comprising using, as the weather-resistant layer-forming coating liquid, a coating liquid that contains a silicone-acrylic composite resin to thereby form a first weather-resistant layer, and further applying, onto the first weather-resistant layer, a coating liquid that contains a fluoropolymer to thereby form a second weather-resistant layer.

31. A solar cell back sheet provided with a solar cell protective sheet, wherein the solar cell protective sheet comprises:
a polyester support having a thickness of from 145 μm to 300 μm, a thermal shrinkage in an in-plane first direction after aged at 150° C. for 30 minutes of from 0.2 to 1.0% and a thermal shrinkage in a second direction perpendicular to the first direction of from −0.3 to 0.5%, and
a polymer layer arranged on at least one side of the polyester support and having a residual solvent amount of at most 0.1% by mass.

32. A solar cell module provided with a solar cell back sheet, wherein the solar cell back sheet is provided with a solar cell protective sheet, and the solar cell protective sheet comprises:
a polyester support having a thickness of from 145 μm to 300 μm, a thermal shrinkage in an in-plane first direction after aged at 150° C. for 30 minutes of from 0.2 to 1.0% and a thermal shrinkage in a second direction perpendicular to the first direction of from −0.3 to 0.5%, and
a polymer layer arranged on at least one side of the polyester support and having a residual solvent amount of at most 0.1% by mass.
